(19) United States
(12) Patent Application Publication
(10) Pub. No.: US 2026/0363023 A1
(43) Pub. Date: Nov. 12, 2026

(54) SUBSTRATE TRANSFER APPARATUS AND SUBSTRATE TRANSFER METHOD

(71) Applicants: KAWASAKI JUKOGYO KABUSHIKI KAISHA, Kobe-shi (JP); Kawasaki Robotics (USA), INC., Wixom, MI (US)

(72) Inventors: Haruhiko TAN, Kobe-shi (JP); Hajime NAKAHARA, San Jose, CA (US)

(73) Assignees: KAWASAKI JUKOGYO KABUSHIKI KAISHA, Kobe-shi (JP); Kawasaki Robotics (USA), INC., Wixom, MI (US)

(21) Appl. No.: 19/200,913

(22) Filed: May 7, 2025

(51) Int. Cl. H10P 72/76; B25J 11/00; B25J 15/00

(52) U.S. Cl. CPC H10P 72/7602; B25J 11/0095; B25J 15/0023; B25J 15/008

(57) ABSTRACT

The substrate transfer apparatus according to one or more embodiments may include a base, an elevator connected to the base freely raised and lowered, and a substrate transport mechanism including a hand that is movably connected to the elevator and transports the substrate. In the substrate transfer apparatus according to one or more embodiments, the hand may include an adhesion pad that adheres to the substrate and grips the substrate, and the adhesion pad may be deformed to change the gripping force of the substrate.

### BACKGROUND

The disclosure relates to a substrate transfer apparatus and a substrate transfer method, and in particular relates to a technique for stably transporting a substrate.

A plurality of manufacturing apparatus are used when manufacturing semiconductor substrates, liquid crystal substrates, panels, and the like (hereinafter collectively referred to as simply “substrates”). Transfer devices are used to transport substrates between these manufacturing devices. The substrate transfer devices are widely used as industrial robots.

U.S. Pat. No. 10,875,190 (Cutkosky) discloses pads for use, augmentation, or retrofitting in robotic manipulators. In Cutkosky, the pad identifies a dry adhesive layer with a dry adhesive wedge that interfaces with the object to be manipulated. The plurality of dry adhesive wedges are arranged in such a way that the pattern has at least two different directions for the direction of the plurality of wedges. The pad further identifies the sensor array under the dry adhesive layer. The data obtained from the sensor array provides an estimate of the shape and size of the contact between the adhesive pad and the object when the dry adhesive layer is in contact with the object.

### SUMMARY

The substrate transfer apparatus according to one or more embodiments may include the following; a base, an elevator connected to the base to be freely raised and lowered, a substrate transport mechanism including, and a hand that is movably connected to the elevator and transports the substrate. In the substrate transfer apparatus according to or more embodiments, the hand may include adhesion pads that adhere to the substrate and grip the substrate, and the adhesion pads may change the gripping force of the substrate by being deformed.

The substrate transfer method according to one or more embodiments may include the following, in which the substrate is placed in contact with the adhesion pads included in the hand of the substrate transfer apparatus, and the tip portions of the adhesion pads are attached to the substrate in the first area, the substrate is transferred while the substrate is placed on the hand, the tip portion of the adhesion pad adheres to the substrate in the second area which is smaller than the first area, and the substrate is placed from the hand onto a certain device.

### BRIEF DESCRIPTION OF DRAWINGS

FIG. 1 is a diagram illustrating an upper surface of a substrate transfer apparatus according to one or more embodiments.

FIG. 2 is a diagram illustrating a top view of a hand included in the substrate transfer apparatus according to one or more embodiments.

FIGS. 3A, 3B, and 3C are diagrams illustrating, A-A cross-sectional view of such as is illustrated in FIG. 2 of a substrate transfer apparatus according to one or more embodiments.

FIGS. 4A and 4B are diagrams illustrating A-A cross-sectional view such as is illustrated in FIG. 2 of a substrate transfer apparatus according to one or more embodiments.

FIGS. 5A and 5B are diagrams illustrating A-A cross-sectional view such as is illustrated in FIG. 2 of a substrate transfer apparatus according to one or more embodiments.

FIGS. 6A, 6B, and 6C are diagrams illustrating A-A cross-sectional view such as is illustrated in FIG. 2 of a substrate transfer apparatus according to one or more embodiments.

FIGS. 7A and 7B are diagrams illustrating for example, A-A cross-sectional view of FIG. 2 of a substrate transfer apparatus according to one or more embodiments.

FIG. 8 is a flowchart of a substrate transfer method according to one or more embodiments.

FIG. 9 is a diagram illustrating a substrate transfer method according to one or more forms.

FIG. 10 is a diagram illustrating a perspective view of a substrate transfer apparatus according to one or more embodiments.

FIG. 11 is a diagram illustrating a perspective view of a substrate transfer apparatus according to one or more embodiments.

FIG. 12 is a diagram illustrating a partially fractured perspective view of a substrate transfer apparatus according to one or more embodiments.

### DETAILED DESCRIPTION

The substrate transfer apparatus according to one or more embodiments is described in detail with reference to the drawings. In the description of the drawings, identical or similar parts may be denoted by the same or similar numerals. The description in the drawing is schematic, and the relationship between thickness and dimensions, the ratio of the length and thickness of each part, etc. are examples, and do not limit the scope of technical concept. Dimensional relationships and dimension ratios may vary between drawings. In the following description, when explaining the positional relationship of each component, “top”, “bottom”, “right side”, “left side”, etc. are appropriately used based on the orientation of the drawing to be referenced and the specific object, but these indications do not limit the scope of technical thought. Expressions such as “top”, “bottom”, “right side”, “left side”, etc. may be used even when each part is not touched. “Longitudinal direction” may mean the direction of the long side on the main surface of the member. “Width direction” may mean the direction of the short side on the main surface of the member. “Height direction” or “vertical direction” may mean a direction related to the thickness of the main surface of the member. Further, the substrate includes, for example, a semiconductor wafer and a glass wafer, and the semiconductor wafer includes a silicon wafer, a sapphire (single crystal alumina) wafer, and various other wafers and panels.

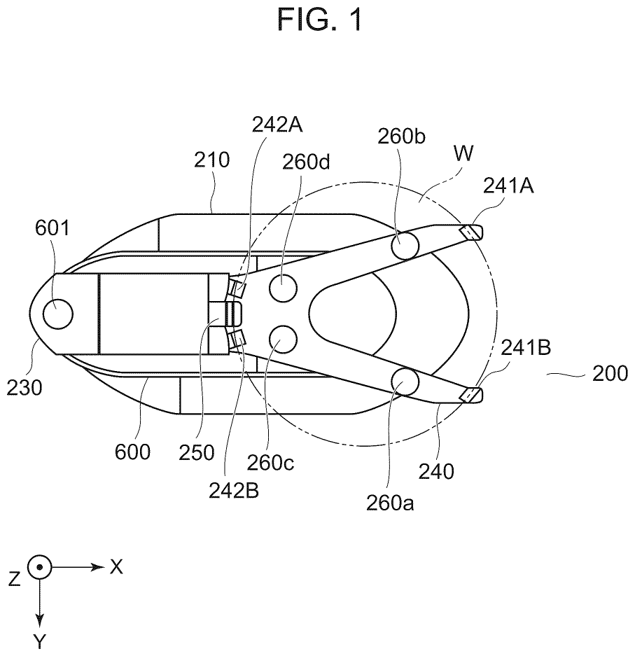

FIG. 1 is a diagram showing the upper surface of the substrate transfer apparatus 200 according to one or more embodiments. The substrate transfer apparatus 200 includes the base 210, an elevator, and a substrate transfer mechanism for transporting the substrate. The elevator is provided to elevate and lower the link 600 and the end effector 230 freely in the vertical direction (Z direction shown). The substrate transport mechanism includes a link 600 rotatably connected to the base 210 and the end effector 230 that is rotatably connected around the rotating shaft 601 and transports the substrate W. Although, the substrate transfer apparatus 200 of FIG. 1 illustrates only one link 600, but may include two, three, four, and five links 600. Further, the substrate transfer apparatus 200 may not include the link 600 and may directly connect the end effector 230 to an elevator (not shown). Further, the substrate transfer apparatus 200 may not include an elevator and may be directly connected to one or more links to the base 300. The substrate transfer apparatus 200 of FIG. 1 particularly indicates a horizontally articulated substrate transfer apparatus, but is not limited to this, and a so-called direct-acting substrate transfer apparatus that does not have a joint or a rotator may also be implemented. In the substrate transfer apparatus 200, various operations are controlled by a controller (not shown). The controller performs various operation controls including lifting and lowering operations and rotation operations of the elevator, link 600, and end effector 230.

The end effector 230 may include a hand 240 that grips the substrate W and the plunger 250 that grips and aligns the substrate in contact with the substrate W. The hand 240 may include substrate contact portions 241a, 241b, 242a, and 242b. The plunger 250 may grips the substrate W. The end effector 230 acquires the substrate W from a predetermined position using the hand 240 under the control of the controller, and transports the substrate W to the predetermined position. When acquiring the substrate W stored in the FOUP (Front Opening Unified Pod) or the like, the hand 240 enters the upper or lower part of the substrate W, and when it is recognized that the hand 240 has entered to a predetermined position of the substrate W, the hand 240 stops approaching. Thereafter, a gripping operation of the substrate W is performed. At this time, the plunger 250 may move and grips the substrate W. As a method for the hand 240 to grip the substrate W, a so-called edge grip method may be used. Thereby, the end effector 230 may grip the substrate W and convey the substrate W to a predetermined position. In the substrate transfer apparatus according to one or more embodiments, it may be implemented without including any or both of the plunger 250 and the substrate contact portions 241a, 241b, 242a and 242b.

The hand 240 includes adhesion pads 260a, 260b, 260c and 260d. The adhesion pads 260a, 260b, 260c and 260d adhere to the substrate W when the substrate W is placed on the hand 240. When the substrate W is placed on the hand 240, the adhesion pads 260a, 260b, 260c and 260d adhere to the substrate W. The adhesion force of the adhesion pads 260a, 260b, 260c and 260d stably hold the substrate W on the hand 240. When the hand 240 then moves the substrate W to a predetermined position, the substrate W is stably moved on the hand 240 by the adhesion force of the adhesion pads 260a, 260b, 260c and 260d.

The adhesion pads 260a, 260b, 260c and 260d each include a tip portion, and the tip portion is attached to the substrate W. The controller (not shown) that controls the substrate transfer apparatus 200 changes the shape of the tip portions of the adhesion pads 260a, 260b, 260c and 260d. By changing the shape of the tip portions, the area attached to the substrate W is changed. Thereby, by changing the adhesion force to the substrate W, and it may be possible to change the adhesion force to the substrate W at the time of transportation depending on the required accuracy.

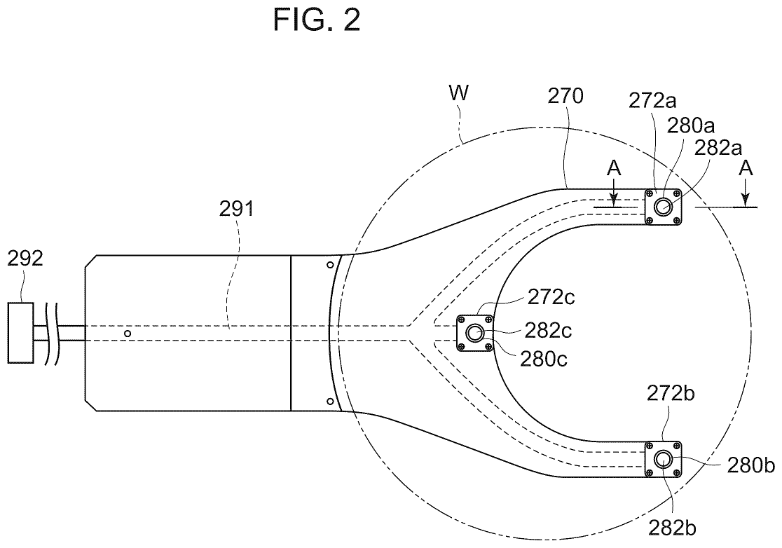

FIG. 2 is a top view showing a hand 270 included in a substrate transfer apparatus according to one or more embodiments. The hand 270 includes two branched portions for stably gripping the substrate W. The hand 270 includes adhesion pads 280a, 280b, and 280c.

The adhesion pads 280a and 280b are placed near the tip of the two branched portions of the hand 270, respectively, and the adhesion pad 280c is placed near the base of the hand 270. The hand 270 includes covers 272a, 272b, and 272c. The covers 272a, 272b, and 272c each have openings arranged in substantially the center. The controller 292 controls the operation of the adhesion pads 280a, 280b, and 280c. The controller 292 controls the tip portions provided in the adhesion pads 280a, 280b, and 280c, respectively. In FIG. 2, hand 270 includes, but is not limited to, three adhesion pads 280a, 280b, and 280c. The hand 270 may be provided with one, two, four, five, six, seven, eight, or more adhesion pads.

The adhesion pads 280a, 280b, and 280c may include silicone rubber, elastomeric polyimide fibers, fluorine rubber, polyurethane. Further, the adhesion pads 280a, 280b, 280c and 280d may use a technique using biomimetics (biomimetic technology) that analyzes and applies superior functions to engineering. For example, a reversible bonding technology that may repeatedly perform bonding and separation, an adhesive technology using Van der waals force, and a dry bonding technology that exhibits adhesive strength without using a sticky liquid.

The hand 270 includes a passage 291 that transmits control of the controller 292 to the adhesion pads 280a, 280b and 280c. The passage 291 is connected to the controller 292 external to the hand 270 from the adhesion pads 280a, 280b and 280c. The operation of the adhesion pads 280a, 280b, and 280c is controlled by the controller 292 through a passage 291 provided inside the hand 270. As shown in FIG. 2, the passage 291 is connected to the controller 292 from near the base of the hand 270. The passage 291 branches from near the base of the hand 270 and is connected to the adhesion pads 280a, 280b and 280c. Not limited to the configuration of the passage 291 shown in FIG. 2, each of the passages 291 from the adhesion pads 280a, 280b and 280c may be connected to the controller 292. In this case, the controller 292 may be able to perform individual operation control for each adhesion pad 280a, 280b, and 280c. The passage 291 may be arranged on the top, back, or inside of the hand 270.

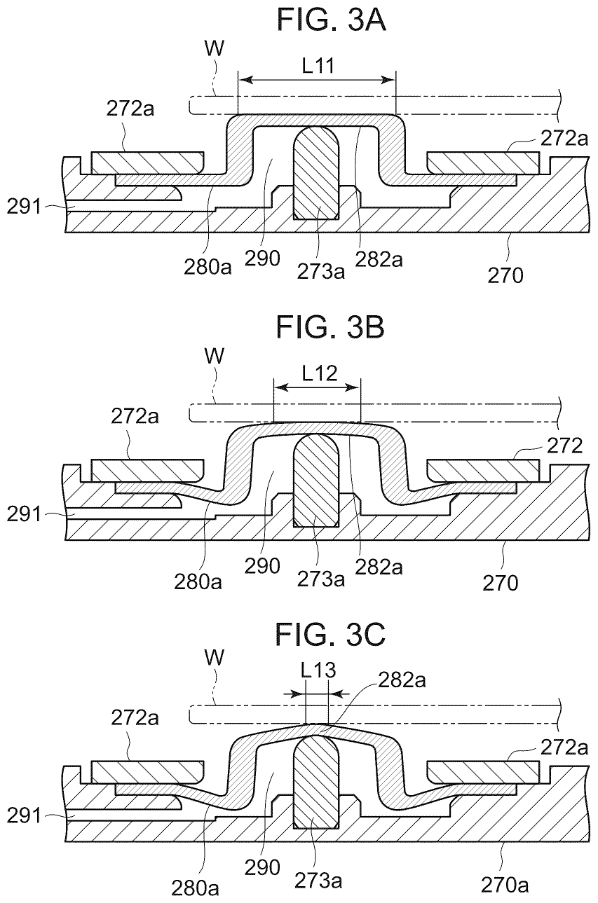

FIGS. 3A, 3B and 3C are diagrams illustrating for example, the A-A cross-sectional view of FIG. 2 of the substrate transfer apparatus according to one or more embodiments. In FIG. 3A, the hand 270 includes the adhesion pad 280a, the pad support 273a that supports the adhesion pad 280a, the cover 272a that covers the adhesion pad 280a, and a cavity 290 provided inside the hand 270. The upper part of the cavity 290 is sealed by an adhesion pad 280a. The cavity 290 is connected to the passage 291. The inside of the passage 291 forms a continuous hollow space extending from the cavity 290. Thereby, the air pressure of the cavity 290 changes by controlling the air pressure in the passage 291. The adhesion pad 280a includes a flat plate shaped flat portion and a tip portion 282a in the substantially center of the flat portion. The flat plate-shaped end of the adhesion pad 280a is sandwiched between the hand 270 and the cover 272a. Thereby, the cavity 290 has a structure having a sealed state blocked from the external environment. The pad support 273a is provided inside the cavity 290 and comes into contact with the bottom surface of the cavity 290 and the substantial center of the tip portion 282a of the adhesion pad 280a. The portion in contact with the adhesion pad 280a of the pad support 273a according to one or more embodiments may be hemispherical as shown.

In FIG. 3A, the tip portion 282a of the adhesion pad 280a is protruded from the opening of the cover 272a. When the substrate W is placed on the hand 270, the tip portion 282a of the adhesion pad 280a adheres to the substrate W. In the state of FIG. 3A, when the tip portion 282a is circular, it adheres to the substrate W in an area according to the diameter L11. The larger the area where the tip portion 282a adheres to the substrate W, the more the adhesion force increases, and the conveyance speed, the conveying acceleration, and the conveying deceleration may be improved. On the other hand, it may be preferable that the adhesion area is as small as possible considering contamination on the substrate W. Further, the material of the adhesion pad 280a is related to the adhesion force and may be a factor for determining the adhesion area. For this reason, it may be preferable to determine the area to which the adhesion pad 280a is attached in consideration of the balance of materials, contamination as well as the required conveying speed. When the tip portion 282a is round, the diameter L11 is preferably 2 mm to 30 mm, and 5 mm to 15 mm may be preferable in terms of the balance.

The tip portion 282a of the adhesion pad 280a grips the substrate W by adhesion force. The tip portion 282a may adhere to the substrate W by stickiness force and friction force. The adhesion force may refer to the force that adheres to the substrate W at least one of the stickiness or friction force. Therefore, the tip portion 282a may adhere to the substrate W by either stickiness force or friction force. Here, the stickiness force may be defined as the force that pulls off two bonded objects. Frictional force may be defined as the force generated when two objects come into contact and try to move relatively. The stickiness force generates a force that resists forces in various directions. On the other hand, the friction force generates a force in the opposite direction to the direction of motion of two objects.

FIG. 3B is A-A cross-sectional view of FIG. 2, for example. In FIG. 3B, the tip portion 282a of the adhesion pad 280a is deformed based on the control of the controller 292. As a result of this deformation, in FIG. 3B, the tip portion 282a adheres to the substrate W with a length of diameter L12 shorter than the diameter L11. The tip portion 282a adheres to the substrate W in an area corresponding to the length of the diameter L12 that is shorter than the diameter L11.

FIG. 3C is A-A cross-sectional view of FIG. 2, for example. In FIG. 3C, the tip portion 282a of the adhesion pad 280a is further deformed based on the control of the controller 292. As a result of this deformation, in FIG. 3C, the tip portion 282a adheres to the substrate W in an area related to the length of the diameter L13 which is shorter than the diameter L12. The diameter L13 is preferably shorter than the diameter L11, and may be preferably point contact.

In the state of FIG. 3A, the tip portion 282a adheres to the area corresponding to the length of the diameter L11 on the substrate W. I understand the following matters. Proceed with the process. Thank you in advance! MO. The controller 292 deforms the tip portion 282a of the adhesion pad 280a to the state of FIG. 3B. In the state of FIG. 3B, the tip portion 282a adheres to the substrate W in an area related to the length of the diameter L12 which is shorter than the diameter L11. The controller 292 further deforms the tip portion 282a, and in the state of FIG. 3C, the tip portion 282a adheres to the substrate W in an area corresponding to the length of the diameter L13 which is shorter than the diameter L12. If the area where the tip portion 282a adheres to the substrate W is large, the force of the tip portion 282a adhering to and gripping the substrate W is increased. Further, if the area where the tip portion 282a adheres to the substrate W is small, the force of the tip portion 282a adhering to and gripping the substrate W is reduced. Therefore, comparing FIGS. 3A, 3B and 3C, the state shown in FIG. 3A has the greatest force of the tip portion 282a to adhere to and grip the substrate W, the state shown in FIG. 3B has the next largest adhesion and gripping force of the tip portion 282a to the substrate W, and the state shown in FIG. 3C has the least adhesion and gripping force of the tip portion 282a to the substrate W.

In FIG. 3A, when the substrate W is placed on the hand 270, the tip portion 282a of the adhesion pad 280a adheres to the substrate W. For example, when high accuracy is required for the placement of the substrate, such as transportation from the pre-aligner device to the load lock device, the adhesion pad 280a increases the area attached to the substrate W and grips the substrate W. Thereby, the misalignment of the substrate W may be reduced.

On the other hand, when high accuracy is not required for the placement of the substrate, such as, for example, from the load port device to the pre-aligner device or from the load lock device to the load port device, the adhesion pad 280a reduces the area adhering to the substrate W and grips the substrate W. Thereby, it may be possible to process transporting the substrate W and handling to other devices at high speed.

As shown in FIG. 2, the tip portions 282a, 282b, and 282c of the adhesion pads 280a, 280b and 280c are circular shape when viewed from above, but may be implemented without limitation. If the adhesion area of the tip portions 282a, 282b and 282c to the substrate W is small, the desired adhesion force may not be obtained. In this case, misalignment or the like may occur when transporting the substrate W. On the other hand, if the adhesion area of the tip portions 282a, 282b and 282c to the substrate W is large, it may be difficult to peel off from the substrate W, and the handling throughput of the substrate W may be reduced. Furthermore, if the adhesion area of the tip portions 282a, 282b and 282c to the substrate W is large, the possibility of contamination increases on the substrate W. Therefore, it may be preferable to design the size and material of the tip portions 282a, 282b and 282c by taking them into consideration.

The controller 292 controls the operation of the adhesion pad 280a. In the substrate transfer apparatus according to one or more embodiments, the controller 292 controls the air pressure in the cavity 290 through the passage 291. For example, in the state of FIG. 3A, the controller 292 controls the cavity 290 to the first pressure. Next, when shifting to the state of FIG. 3B, the controller 292 controls the air pressure of the cavity 290 to the second pressure which is lower than the first pressure. Further, when moving to the state of FIG. 3C, the controller 292 controls the air pressure of the cavity 290 to the third pressure which is lower than the second pressure. For example, when the first pressure is the ambient pressure at the place where the substrate transfer apparatus is installed, the second pressure and the third pressure may be lower than the ambient pressure. Further, when the first pressure is positive pressure, the second pressure or the third pressure may be an ambient pressure. Here, in order to reduce contamination from particulate matter, scientific substances, or biological substances from the substrate transport environment, it may be preferable that the cavity 290 is in a negative pressure state at all times. For example, the controller 292 may control the cavity 290 to a first pressure that is a negative pressure lower than the ambient pressure, and to control the second and third pressure lower than the first pressure. Further, it may be preferable to use CDA (Clean Dry Air) when positive pressure is applied.

For example, the controller may include a vacuum regulator for the air pressure control of the cavity 290 by the controller 292. A vacuum regulator is a device that controls negative pressure to maintain a constant pressure. The vacuum regulator includes a pump that is a vacuum source, and may include a decompression unit that adjusts pressure, an outlet connected to the passage 291, and a sensor that detects pressure inside the cavity 290. When the controller 292 controls to the first pressure, the cavity 290 is depressurized through the outlet by a decompression unit. When the sensor detects that the cavity 290 has reached the first pressure, the decompression unit stops depressurizing. Next, when the controller 292 controls to the second pressure, the controller 292 depressurizes or pressurizes the inside of the cavity 290 through the outlet by the decompression unit. When the sensor detects that the cavity 290 has reached the second pressure, the decompression unit stops depressurizing or pressurizing. The controller 292 may include the first decompression unit that controls the first pressure, the second decompression unit that controls the second pressure, and a switching valve for switching between the first pressure of the decompression unit or the second pressure of the second decompression unit. When the first pressure is the ambient pressure, a valve may be provided in the controller to return the negative pressure of the cavity 290 to the ambient pressure.

In FIG. 3A, when the controller 292 is controlled to the first pressure, the adhesion pad 280a is flat and substantially parallel to the cover 272a. Further, the pad support 273a is provided inside the cavity 290, and contacts the bottom surface of the cavity 290 and the tip portion 282a to support the adhesion pad 280a. The cavity 290 has a sufficient area. In this case, the distance between the substrate W and the cover 272a is the length L11. Next, in the state of FIG. 3B, that is, when the controller 292 is controlled at the second pressure lower than the first pressure, the adhesion pad 280a changes to a recessed shape on the cavity 290 side due to the difference in air pressure in the cavity 290 and the external air pressure. Accordingly, adhesion to the substrate W is released from the periphery of the tip portion 282a. The periphery of the tip portion 282a is separated from the substrate W, but the center of the tip portion 282a is supported by the pad support 273a, and therefore adheres to the substrate W. In the state of FIG. 3B, the adhesion area between the tip portion 282a and the substrate decreases compared to the state of FIG. 3A. Accordingly, the gripping force of the substrate also decreases. Next, in the state of FIG. 3C, that is, when the controller 292 is controlled at a third pressure lower than the second pressure, the adhesion pad 280a changes to a shape that is further recessed on the cavity 290 side due to the difference in air pressure in the cavity 290 and the external pressure. Accordingly, the adhesion to the substrate W is further released from the periphery of the tip portion 282a, and the adhesion area between the tip portion 282a and the substrate W is reduced. Adhesion to the substrate W is further released from the periphery of the tip portion 282a, but the center of the tip portion 282a is supported by the pad support 273a, and therefore adheres to the substrate W. In the state of FIG. 3C, the adhesion area between the tip portion 282a and the substrate decreases compared to the state of FIG. 3B. Accordingly, the gripping force of the substrate also decreases.

As described above, in the substrate transfer apparatus according to one or more embodiments, the adhesion pad 280a adheres to the substrate W based on the control of the controller 292. By using the adhesion force of the adhesion pad 280a, the adhesion area of the adhesion pad 280a is increased when the substrate W is transported with acceleration or deceleration, and when the substrate W is placed on the FOUP, for example, the adhesion area is reduced. Thereby, it may be possible to reduce the adverse effect of the adhesion force of the adhesion pad 280a. Although the above description refers to the adhesion pad 280a, the same configuration may be used for the other adhesion pads 280b and 280c. The following description also applies to other adhesion pads than those described above.

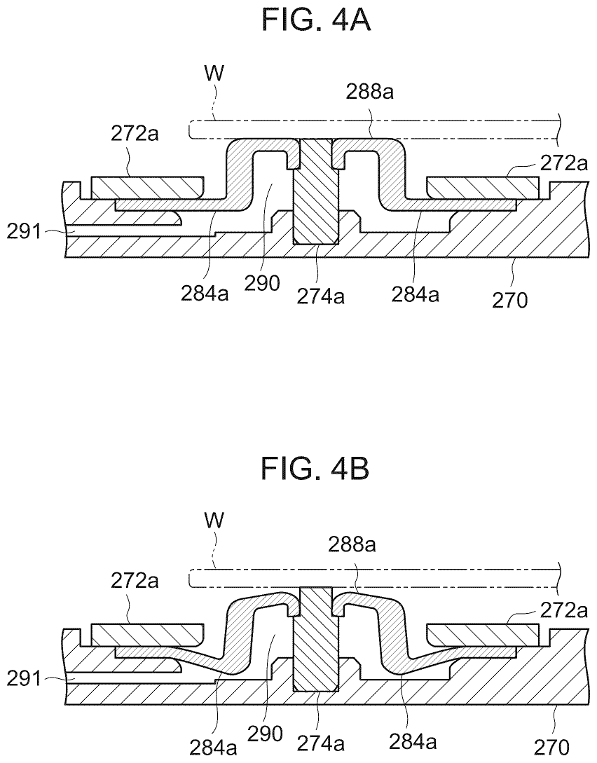

FIGS. 4A and 4B are diagrams illustrating for example, A-A cross-sectional view of FIG. 2 of the substrate transfer apparatus according to one or more embodiments. In FIG. 4A, the hand 270 includes the adhesion pad 284a, the pad support 274a that supports the adhesion pad 284a, the cover 272a covering the adhesion pad 284a, and the cavity 290 provided inside the hand 270. The pad support 274a contacts the adhesion pad 284a at the top of the cavity 290 and seals the cavity 290. The pad support 274a of the substrate transfer apparatus according to one or more embodiments has a structure that adheres to the substrate W. The cavity 290 is connected to the passage 291. The inside of the passage 291 forms a continuous hollow space extending from the cavity 290. Thereby, the air pressure of the cavity 290 changes by controlling the air pressure of the passage 291. The adhesion pad 284a includes a flat plate shaped flat portion and a tip portion 288a in the substantially center of the flat portion. The flat plate shape end of the adhesion pad 284a is sandwiched between the hand 270 and the cover 272a. Further, the flat plate shape of the adhesion pad 284a is integrally formed with the tip portion 288a, and the tip portion 288a and the pad support 274a are connected so as to seal the cavity 290. Thereby, the cavity 290 has a structure that is sealed off from the external environment. The pad support 274a comes into contact with the bottom surface of the cavity 290 and the approximate center of the tip portion 288a of the adhesion pad 284a. Further, the pad support 274a is protruded from the substantially center of the tip portion 288a to a position where it adheres to the substrate W.

In FIG. 4A, the tip portion 288a of the adhesion pad 284a is protruded from the opening of the cover 272a. When the substrate W is placed on the hand 270, the tip portion 288a of the adhesion pad 284a and the pad support 274a adhere to the substrate W. In the state of FIG. 4A, the tip portion 288a adheres to the substrate W in a predetermined area. Also, the pad support 274a adheres to substrate W in a predetermined area. When the tip portion 288a is circular, the tip portion 288a may preferably adheres to the substrate W with an area pertaining to 2 mm to 30 mm in diameter, and may furthermore adhere to the substrate W with an area pertaining to 5 mm to 15 mm in diameter when the tip portion 288a is circular. In addition, it may be preferable that the area where the pad support 274a adheres to the substrate W is sufficient to hold the substrate W.

The tip portions 288a of the adhesion pad 284a and the pad support 274a grip the substrate W by adhesion force. The tip portion 288a and the pad support 274a may adhere to the substrate W with stickiness force and friction force. The adhesion force may refer to the force that adheres to the substrate W by at least one of the stickiness force or friction force. Therefore, the tip portion 288a and the pad support 274a may adhere to the substrate W by either stickiness force or friction force. Here, the stickiness force may be defined as the force that pulls off two bonded objects apart. The friction force may be defined as the force generated when two objects come into contact and try to move relatively. The stickiness force generates a force that resists forces in various directions. On the other hand, the friction force generates a force in the opposite direction to the direction of motion of two objects. The tip portion 288a of the adhesion pad 284a and the pad support 274a may have different adhesion forces. For example, if the tip portion 288a has the first adhesion force, the pad support 274a may have the second adhesion force that is weaker than the first adhesion force. Furthermore, the tip portion 288a and the pad support 274a may include different materials.

The adhesion pad 284a may include silicon rubber, elastomeric polyimide fiber, fluorine rubber, polyurethane, or the like. Further, the adhesion pad 284a may use a technique using biomimetics (biomimetic technology) that analyzes and engineer excellent functionality. For example, a reversible bonding technology that may repeatedly perform adhesion and separation, an adhesive technology using Van der waals force, and a dry adhesive technology that exhibits adhesive strength without using a sticky liquid. Further, the pad support 274a may include silicon rubber, elastomeric polyimide fiber, fluorine rubber, engineering plastics including PEEK (Polyetheretherketone), polyurethane, and the like. Further, the pad support 274a may have an adhesion force by the friction force only. In other words, the pad support 274a may include a non-stickiness material.

FIG. 4B is A-A cross-sectional view of FIG. 2, for example. In FIG. 4B, based on the control of the controller 292, the tip portion 288a of the adhesion pad 284a is deformed. As a result of this deformation, in FIG. 4B, the tip portion 288a is separated from the substrate W and the adhesion is released. On the other hand, the pad support 274a remains attached to the substrate W.

In the state of FIG. 4A, the tip portion 288a and the pad support 274a adhere to the substrate W. By deforming the tip portion 288a of the adhesion pad 284a, the tip portion 288a is released from adhesion to the substrate W as shown in the state of FIG. 4B, and only the pad support 274a is attached to the substrate W. When the tip portion 288a is attached to the substrate W, the force of the tip portion 288a adhering to and gripping the substrate W is greater. When the tip portion 288a is separated from the substrate W and only the pad support 274a is attached, the force of the pad support 274a adhering to and gripping the substrate W is smaller. Therefore, when comparing FIGS. 4A and 4B, the state shown in FIG. 4A has a larger force of the tip portion 288a to adhere to and grip the substrate W, while the state shown in FIG. 4B has a smaller force of the pad support 274a to adhere to and grip the substrate W.

In FIG. 4A, when the substrate W is placed on the hand 270, the tip portions 288a of the adhesion pad 284a and the pad support 274a are attached to the substrate W. For example, when high accuracy is required for the placement of the substrate W, such as transportation from the pre-aligner device to the load lock device, the tip portion 288a and the pad support 274a adhere to and grip the substrate W. Thereby, the misalignment of the substrate W may be reduced.

On the other hand, when high accuracy is not required for the placement of the substrate, such as, for example, from the load port device to the pre-aligner device or from the load lock device to the load port device, only the pad support 274a adheres to and grips the substrate W. Thereby, it may be possible to process transporting the substrate W and handling to other devices at high speed.

As shown in FIG. 2, the tip portions 282a, 282b and 282c of the adhesion pads 280a, 280b and 280c are circular when viewed from above, but the adhesion pads 284a and pad support 274a shown in FIGS. 4A and 4B may be implemented without limitation. If the adhesion area of the tip portion 288a to the substrate W is small, the desired adhesion force may not be obtained. In this case, there may be a possibility of misalignment or the like when transporting the substrate W. On the other hand, if the adhering portion of the tip portion 288a to the substrate W is large, it may be difficult to peel off from the substrate W, and the throughput of handling the substrate W may be reduced. Furthermore, if the adherence portion of the tip portion 288a to the substrate W is large, the possibility of contamination of the substrate W increases. Therefore, it may be preferable to design the size and material of the tip portion 288a and the pad support 274a by taking them into consideration.

The controller 292 controls the operation of the adhesion pad 284a. In the substrate transfer apparatus according to one or more embodiments, the controller 292 controls the air pressure in the cavity 290 through the passage 291. For example, in the state of FIG. 4A, the controller 292 controls the cavity 290 to the first pressure. Next, when moving to the state of FIG. 4B, the controller 292 controls the air pressure in the cavity 290 to the second pressure which is lower than the first pressure. For example, when the first pressure is an ambient pressure, the second pressure may be a negative pressure lower than the ambient pressure. Further, when the first pressure is positive pressure, the second pressure may be the ambient pressure. Here, in order to reduce contamination from particulate matter, scientific substances, or biological substances from the substrate transport environment, the cavity 290 is preferably in a negative pressure state at all times. For example, the controller 292 may control the cavity 290 to the first pressure that is a negative pressure lower than the ambient pressure and to control it to the second pressure lower than the first pressure. Further, when positive pressure is used, it may be preferable to use CDA (Clean Dry Air).

In FIG. 4A, when the controller 292 controls the air pressure to the first pressure, the adhesion pad 284a is flat and substantially parallel to the cover 272a. The pad support 274a is provided inside the cavity 290, adheres to the bottom surface of the cavity 290 and the tip portion 288a, and supports the adhesion pad 284a. Further, the pad support 274a is protruded from the tip portion 288a and adheres to the substrate W. The cavity 290 has a sufficient area. The surface of the tip portion 288a and the surface of the pad support 274a are positioned at approximately constant height. In this case, the tip portion 288a and the pad support 274a adhere to the substrate W. Next, in the state of FIG. 4B, that is, when the controller 292 controls the air pressure to the second pressure which is lower than the first pressure, the adhesion pad 284a changes to a recessed shape on the cavity 290 side due to the difference in air pressure in the cavity 290 and the external air pressure. Accordingly, adhesion to the substrate W is released from the periphery of the tip portion 288a, and eventually, the entire tip portion 288a is released from adhesion to the substrate W. The tip of the pad support 274a remains attached to the substrate W without changing to the air pressure control of the controller 292. Here, since the adhesion force of the pad support 274a is lower than the adhesion force of the adhesion pad 284a, the gripping force of the substrate W is reduced. In the state of FIG. 4B, it may be preferable that the tip portion 288a does not come into contact with the substrate W, and even if it is in contact, it may be preferably a minimum area.

In addition, it may be preferable that the area where the pad support 274a adheres to the substrate W is sufficient to hold the substrate W.

Here, in the hand 270 according to one or more embodiments, as shown in FIG. 4A in the state of the first pressure, both the tip portion 288a of the adhesion pad 284a and the pad support 274a adhere to the substrate W, and in the state of the second pressure, only the pad support 274a adheres to the substrate W. However, it is not limited thereto, for example, in the state of the first pressure, both the tip portion 288a and the pad support 274a adhere to the substrate W, and in the state of the second pressure, only a part of the tip portion 288a and the pad support 274a may be attached to the substrate W. Further, for example, in the state of the first pressure, only the tip portion 288a adheres to the substrate W, and in the state of the second pressure, only the pad support 274a may be attached to the substrate W.

As described above, in the substrate transfer apparatus according to one or more embodiments, based on the control of the controller 292, the adhesion pad 284a is protruded from the hand 270 and adheres to the substrate W. For example, when a high degree of accuracy is required with reducing deviation during transport for placing the substrate, such as from the pre-aligner device to the load lock device, the adhesion pad 284a having high adhesion is attached to the substrate W in a predetermined adhesion area. On the other hand, when high accuracy is not required for substrate placement, such as, for example, from the load port device to the pre-aligner device or from the load lock device to the load port device, the adhesion pad 284a is deformed based on the control of the controller 292 to decrease the adhesion area of the substrate W. As a result, the adhesion force to the substrate W on the hand 270 is reduced, but the substrate transfer speed may be improved. Thus, the adhesion force to the substrate W may be controlled by transforming the adhesion pad 284a provided in the hand 270 and changing the adhesion area between the adhesion pad 284a and the substrate W, and the gripping force during transfer may be changed depending on the required accuracy.

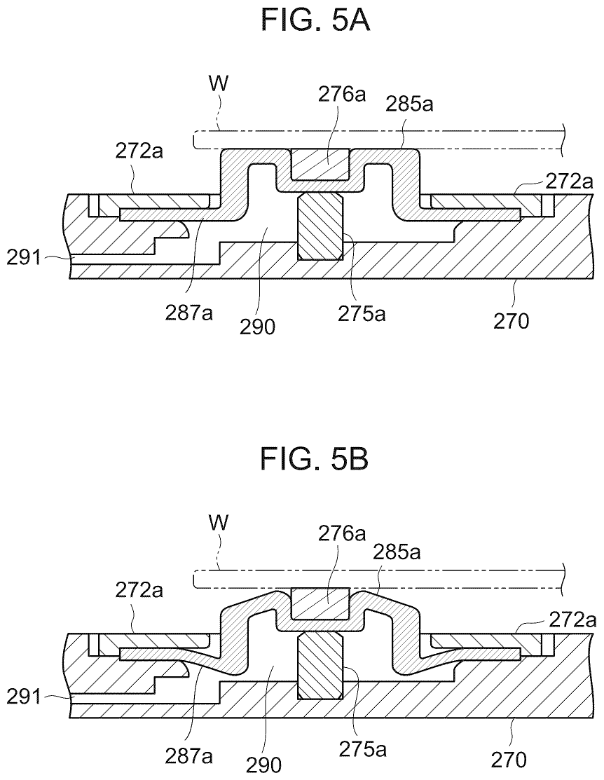

FIGS. 5A and 5B are diagrams illustrating, for example, A-A cross-sectional view of FIG. 2 of the substrate transfer apparatus according to one or more embodiments. In FIG. 5A, the hand 270 includes the first adhesion pad 287a, the second adhesion pad 276a, the pad support 275a supporting the first adhesion pad 287a and the second adhesion pad 276a, the cover 272a covering the first adhesion pad 287a, and the cavity 290 provided inside the hand 270. The pad support 275a comes into contact with the first adhesion pad 287a at the top of the cavity 290. The cavity 290 is connected to the passage 291. The inside of the passage 291 forms a continuous hollow space extending from the cavity 290. Thereby, the air pressure of the cavity 290 changes by controlling the air pressure in the passage 291. The first adhesion pad 287a includes a flat plate shaped flat portion and a tip portion 285a in the substantially center of the flat portion. The flat plate shaped end of the first adhesion pad 287a is sandwiched between the hand 270 and the cover 272a. Further, the flat plate shape of the first adhesion pad 287a is integrally formed with the tip portion 285a, and the tip portion 285a seals the cavity 290. Thereby, the cavity 290 has a structure having a sealed state blocked from the external environment. The pad support 275a comes into contact with the bottom surface of the cavity 290 and the substantially center of the tip portion 285a of the first adhesion pad 287a. The tip portion 285a has a recess in the center area, and the second adhesion pad 276a is placed in a recess.

In FIG. 5A, the tip portion 285a of the first adhesion pad 287a is protruded from the opening of the cover 272a. The protruded tip portion 285a of the first adhesion pad 287a adheres to the substrate W when the substrate W is placed on the hand 270. In the state of FIG. 5A, the tip portion 285a adheres to the substrate W in a predetermined area. Further, the second adhesion pad 276a adheres to the substrate W in a predetermined area.

The tip portions 285a of the first adhesion pad 287a and the second adhesion pad 276a grip the substrate W by adhesion force. The tip portion 285a and the second adhesion pad 276a may adhere to the substrate W with stickiness force and friction force. The adhesion force may refer to the force that adheres to the substrate W by at least one of the stickiness or friction force. Therefore, the tip portion 285a and the second adhesion pad 276a may adhere to the substrate W with either stickiness force or friction force. Here, the stickiness force may be defined as the force that pulls off two bonded objects. The friction force may be defined as the force generated when two objects come into contact and try to move relatively. The stickiness force generates a force that resists forces in various directions. On the other hand, the friction force generates a force in the opposite direction to the direction of motion of two objects. The tip portion 285a of the first adhesion pad 287a and the second adhesion pad 276a may have different adhesion forces. For example, when the tip portion 285a has the first adhesion force, the second adhesion pad 276a may have the second adhesion force that is weaker than the first adhesion force. Further, the tip portion 285a and the second adhesion pad 276a may include different materials.

The first adhesion pad 287a may include silicon rubber, elastomeric polyimide fibers, fluorine rubber, polyurethane, and the like. Further, the first adhesion pad 287a may use a technique using biomimetics (biomimetic technology) that analyzes excellent functions and applies them engineering. For example, a reversible bonding technology that may repeatedly perform adhesion and separation, an adhesive technology using Van der waals force, and a dry adhesive technology that exhibits adhesive strength without using a sticky liquid. The second adhesion pad 276a may also include silicon rubber, elastomeric polyimide fiber, fluorine rubber, engineering plastic containing (Polyetheretherketone) and polyurethane, or the like. Further, the second adhesion pad 276a may have an adhesion force only by the friction force. In other words, the second adhesion pad 276a may include a non-stickiness material.

FIG. 5B is A-A cross-sectional view of FIG. 2, for example. In FIG. 5B, based on the control of the controller 292, the tip portion 285a of the first adhesion pad 287a is deformed. As a result of this deformation, in FIG. 5B, the tip portion 285a is separated from the substrate W and the adhesion is released. On the other hand, the second adhesion pad 276a remains attached to the substrate W.

In the state of FIG. 5A, the tip portion 285a and the second adhesion pad 276a adhere to the substrate W. The controller 292 deforms the tip portion 285a, so that the tip portion 285a is released from adhesion to the substrate W as shown in the state of FIG. 5B, and only the second adhesion pad 276a is attached to the substrate W. When the tip portion 285a is attached to the substrate W, the force with which the tip portion 285a and the second adhesion pad 276a adhere to and grip the substrate W increases. Further, when the tip portion 285a is separated from the substrate W and only the second adhesion pad 276a is attached, the gripping force becomes smaller. Therefore, comparing FIGS. 5A and 5B, the state shown in FIG. 5A has a larger force for the tip portion 285a and the second adhesion pad 276a to adhere to and grip the substrate W, and the state shown in FIG. 5B has a smaller force for the second adhesion pad 276a to adhere to and grip the substrate W.

In FIG. 5A, when the substrate W is placed on the hand 270, the tip portions 285a of the adhesion pad 284a and the second adhesion pad 276a adhere to the substrate W. For example, when high accuracy is required for the placement of the substrate W, such as transportation from the pre-aligner device to the load lock device, the tip portion 285a and the second adhesion pad 276a adhere to the substrate W. Thereby, the misalignment of the substrate W may be reduced.

On the other hand, when high accuracy is not required for the placement of the substrate W, for example, from the load port device to the pre-aligner device or from the load lock device to the load port device, only the second adhesion pad 276a adheres to the substrate W. Thereby, it may be possible to process transporting the substrate W and handling to other devices at high speed.

As shown in FIG. 2, the tip portions 282a, 282b and 282c of the adhesion pads 280a, 280b and 280c show a circular shape when viewed from above, but the first adhesion pad 287a and the second adhesion pad 276a shown in FIGS. 5A and 5B may be implemented without limitation. If the adhesion area of the tip portion 285a to the substrate W is small, the desired adhesion force may not be obtained. In this case, there is a possibility of misalignment or the like when transporting the substrate W. On the other hand, if the adhering area of the tip portion 285a to the substrate W is large, it may be difficult to peel off from the substrate W, and the throughput of handling the substrate W may be reduced. Furthermore, if the adhering area of the tip portion 285a to the substrate W is large, the possibility of contamination of the substrate W increases. Therefore, it may be preferable to design the size and material of the tip portion 285a and the second adhesion pad 276a by these into consideration.

The controller 292 controls the operation of the first adhesion pad 287a. In the substrate transfer apparatus according to one or more embodiments, the controller 292 controls the air pressure in the cavity 290 through the passage 291. For example, in the state of FIG. 5A, the controller 292 controls the cavity 290 to the first pressure. Next, when moving on to the state of FIG. 5B, the controller 292 controls the air pressure in the cavity 290 to the second pressure which is lower than the first pressure. For example, when the first pressure is an ambient pressure, the second pressure may be a negative pressure lower than the ambient pressure. Further, when the first pressure is positive pressure, the second pressure may be the ambient pressure. Here, in order to reduce contamination from particulate matter, scientific substances, or biological substances from the substrate transport environment, it is preferable that the cavity 290 is kept under a negative pressure at all times. For example, the controller 292 may control the cavity 290 to the first pressure that is a negative pressure lower than the ambient pressure, and the second pressure lower than the first pressure. Further, when positive pressure is used, it may be preferable to use CDA (Clean Dry Air).

In FIG. 5A, when the controller 292 is controlled to the first pressure, the first adhesion pad 287a is flat and substantially parallel to the cover 272a. The second adhesion pad 276a is placed in the recess and adheres to the substrate W. The cavity 290 has a sufficient area. In this case, the tip portion 285a and the second adhesion pad 276a are attached to the substrate W. Next, in the state of FIG. 5B, that is, when the controller 292 controls the second pressure lower than the first pressure, the first adhesion pad 287a changes to a recessed shape on the cavity 290 side due to the difference in air pressure in the cavity 290 and the external air pressure. Accordingly, adhesion to the substrate W is released from the peripheral of the tip portion 285a, and eventually, the entire tip portion 285a is released from adhesion to the substrate W. Since the second adhesion pad 276a is supported by the pad support 275a from the bottom surface, it remains attached to the substrate W. Here, since the adhesion force of the second adhesion pad 276a is lower than the adhesion force of the first adhesion pad 287a, the gripping force of the substrate W is reduced.

Here, in the hand 270 according to one or more embodiments, in the state of the first pressure as shown in FIG. 5A, both the tip portion 285a of the first adhesion pad 287a and the second adhesion pad 276a adhere to the substrate W, and only the second adhesion pad 276a adheres to the substrate W in the state of the second pressure. However, it is not limited thereto, for example, in the state of the first pressure, both the tip portion 285a and the second adhesion pad 276a adhere to the substrate W, and in the state of the second pressure, a part of the tip portion 285a and the second adhesion pad 276a may adhere to the substrate W. Further, for example, in the state of the first pressure, only the tip portion 285a adheres to the substrate W, and in the state of the second pressure, only the second adhesion pad 276a may adhere to the substrate W.

In the case of FIG. 5A, it may be preferable for the tip portion 285a to adheres to the substrate W in an area pertaining to 2 mm to 30 mm in diameter, and the tip portion 285a may furthermore adheres to the substrate W in an area pertaining 5 mm to 15 mm in diameter. Next, in the case of FIG. 5B, it may be preferable that the tip portion 285a does not come into contact, and even if it does, preferably with a minimum area. Further, it may be desirable for the second adhesion pad 276a to be in contact with an area large enough to stably hold the substrate W.

As described above, in the substrate transfer apparatus according to one or more embodiments, the first adhesion pad 287a and the second adhesion pad 276a are adheres to the substrate W based on the control of the controller 292. For example, when the misalignment at the time of transfer needs to be reduced and high accuracy is required for the placement of the substrate W, such as transportation from the pre-aligner device to the load lock device, the first adhesion pad 287a having high adhesion adheres to the substrate W at a predetermined adhesion area. On the other hand, when high accuracy is not required for the placement of the substrate W, for example, from the load port device to the pre-aligner device or from the load lock device to the load port device, the first adhesion pad 287a is deformed based on the control of the controller 292 and the adhesion area of the substrate W is reduced. As a result, the adhesion force to the substrate W on the hand 270 is reduced, but the substrate transfer speed may be improved. Thus, the adhesion force to the substrate W is controlled by deforming the first adhesion pad 287a provided in the hand 270 and changing the adhesion area between the first adhesion pad 287a and the substrate W, and the gripping force during the transportation may be changed depending on the required accuracy.

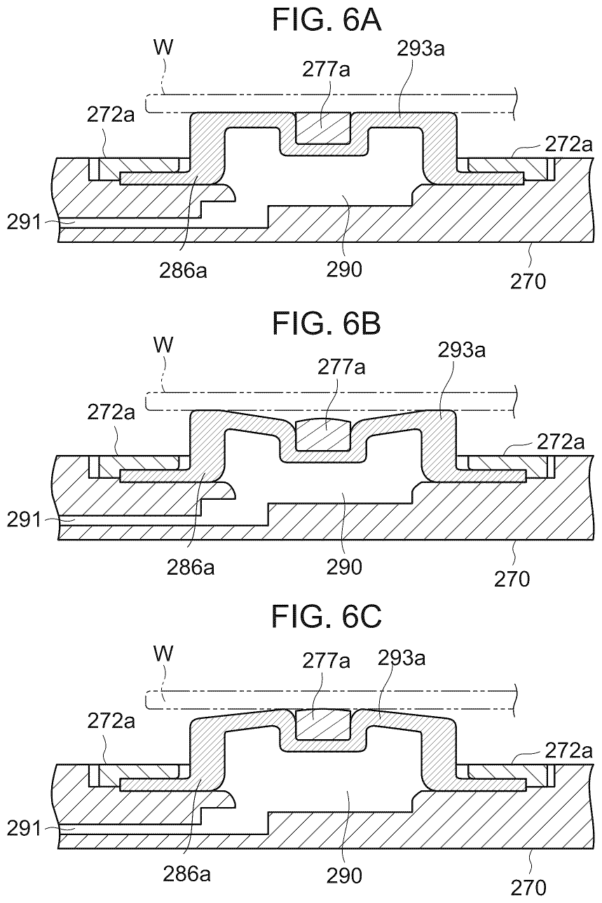

FIGS. 6A and 6B are diagrams illustrating for example, A-A cross-sectional view of FIG. 2 of the substrate transfer apparatus according to one or more embodiments. In FIG. 6A, the hand 270 includes the first adhesion pad 286a, the second adhesion pad 277a, the cover 272a covering the first adhesion pad 286a, and the cavity 290 provided inside the hand 270. The cavity 290 is connected to the passage 291. The inside of the passage 291 forms a continuous hollow space extending from the cavity 290. Thereby, the air pressure of the cavity 290 is changed by controlling the air pressure of the passage 291. The first adhesion pad 286a includes a flat plate shaped flat portion and the tip portion 293a in the substantially center of the flat portion. The flat plate shaped end of the first adhesion pad 286a is sandwiched between the hand 270 and the cover 272a. Further, the flat plate shape of the first adhesion pad 286a is integrally formed with the tip portion 293a, and the tip portion 293a seals the cavity 290. Thereby, the cavity 290 has a structure having a sealed state blocked from the external environment. The tip portion 293a has a recess in the center, and the second adhesion pad 277a is placed in a recess.

In FIG. 6A, the tip portion 293a of the first adhesion pad 286a is protruded from the opening of the cover 272a. The tip portion 293a of the first adhesion pad 286a adheres to the substrate W when the substrate W is placed on the hand 270. In the state of FIG. 6A, the tip portion 293a adheres to the substrate W in a predetermined area. Further, the second adhesion pad 277a adheres to the substrate W in a predetermined area.

The tip portion 293a of the first adhesion pad 286a and the second adhesion pad 277a grip the substrate W by adhesion force. The tip portion 293a and the second adhesion pad 277a may adhere to the substrate W by stickiness force and friction force. The adhesion force may refer to the force that adheres to the substrate W by at least one of the stickiness or friction force. Therefore, the tip portion 293a and the second adhesion pad 277a may adhere to the substrate W by either stickiness force or friction force. Here, the stickiness force may be defined as the force that pulls off two bonded objects. The friction force may be defined as the force generated when two objects come into contact and try to move relative to each other. The stickiness force generates a force that resists forces in various directions. On the other hand, the friction force generates a force in the opposite direction to the direction of motion of two objects. The tip portion 293a of the first adhesion pad 286a and the second adhesion pad 277a may have different adhesion forces. For example, when the tip portion 293a has the first adhesion force, the second adhesion pad 277a may have the second adhesion force weaker than the first adhesion force. Furthermore, the tip portion 293a and the second adhesion pad 277a may include different materials.

The first adhesion pad 286a may include silicon rubber, elastomeric polyimide fiber, fluorine rubber, polyurethane, or the like. Further, the first adhesion pad 286a may use a technique using biomimetics (biomimetic technology) that analyzes excellent functions and applies them engineering. For example, a reversible bonding technology that may repeatedly perform adhesion and separation, an adhesive technology using Van der waals force, and a dry adhesive technology that exhibits adhesive strength without using a sticky liquid. Further, the second adhesion pad 277a may include silicon rubber, elastomeric polyimide fiber, fluorine rubber, polyurethane, or the like. Further, the second adhesion pad 277a may have an adhesion force only by friction force. In other words, the second adhesion pad 277a may include a non-stickiness material.

FIG. 6B is A-A cross-sectional view of FIG. 2, for example. In FIG. 6B, based on the control of the controller 292, the tip portion 293a of the first adhesion pad 286a is deformed. As a result of the deformation in FIG. 6B, the tip portion 293a gradually moves away from the substrate W from the center, and the adhesion is released from the center. Accordingly, the second adhesion pad 277a is also released from the substrate W. Based on the control of the controller 292, the center of the tip portion 293a is separated from the substrate W, and the periphery of the tip portion 293a remains attached to the substrate W. In this state, a sealed space is generated between the second adhesion pad 277a and the substrate W. Since the space was created by recessing the central part of the first adhesion pad 286a, and thus has a lower pressure than the outside pressure. Thereby, the first adhesion pad 286a has a higher grip.

FIG. 6C is A-A cross-sectional view of FIG. 2, for example. In FIG. 6C, based on the control of the controller 292, the tip portion 293a of the first adhesion pad 286a is deformed. As a result of the deformation in FIG. 6C, the center of the tip portion 293a and the second adhesion pad 277a adhere to the substrate W. Based on the control of the controller 292, the periphery of the tip portion 293a is separated from the substrate W, and the center of the tip portion 293a and the second adhesion pad 277a adhere to the substrate W. In this state, since only the center of the tip portion 293a and the second adhesion pad 277a adhere to the substrate W, the first adhesion pad 286a has a lower grip than FIGS. 6A and 6B.

It may be preferable for the tip portion 293a to adheres to the substrate W in an area having a diameter of 2 mm to 30 mm, and furthermore, the tip portion 293a adheres to the substrate W in an area of 5 mm to 15 mm in diameter.

In the state of FIG. 6A, the tip portion 293a and the second adhesion pad 277a adhere to the substrate W. The controller 292 deforms the tip portion 293a, so that the center of the tip portion 293a and the second adhesion pad 277a are released from adhesion to the substrate W as shown in the state of FIG. 6B. In this state, a sealed space is generated between the substrate and the tip portion 293a. Since the space was created by recessing the central part of the first adhesion pad 286a, it has a lower air pressure than the outside air pressure. Thereby, the first adhesion pad 286a has a higher grip to the substrate W. Next, when the cavity 290 is inflated as shown in FIG. 6C, the periphery of the tip portion 293a is separated from the substrate W, and the center of the tip portion 293a and the second adhesion pad 277a are adhered to the substrate W. In this state, since the substrate W is attached to the center of the tip portion 293a and the second adhesion pad 277a, the first adhesion pad 286a has a lower grip than FIGS. 6A and 6B.

In FIG. 6A, when the substrate W is placed on the hand 270, the tip portions 293a of the first adhesion pad 286a and the second adhesion pad 277a adhere to the substrate W. Further, in FIG. 6B, the first adhesion pad 286a is deformed so as to be recessed, and a space with a lower pressure than the outside air pressure is generated between the first adhesion pad 286a and the substrate W. Thereby, the first adhesion pad 286a may increase the gripping force on the substrate W. For example, when high accuracy is required for the placement of the substrate W, such as transportation from the pre-aligner device to the load lock device, a sealed space of negative pressure is generated between the first adhesion pad 286a and the substrate W to grip the substrate W. Thereby, the misalignment of the substrate W may be reduced.

On the other hand, when high accuracy is not required for the placement of the substrate W, for example, from the load port device to the pre-aligner device or from the load lock device to the load port device, the cavity 290 is inflated and the center of the first adhesion pad 286a is lifted as shown in FIG. 6C. As a result, the space shown in FIG. 6B disappears, and further, the periphery of the first adhesion pad 286a is separated from the substrate W and the adhesion is released. The center of the tip portion 293a and the second adhesion pad 277a are attached to the substrate W. Thereby, it may be possible to process transporting the substrate W and handling to other devices at high speed.

As shown in FIG. 2, the tip portions 282a, 282b and 282c of the adhesion pads 280a, 280b and 280c show a circular shape when viewed from above, but the first adhesion pad 286a and the second adhesion pad 277a shown in FIGS. 6A, 6B and 6C may be implemented without limitation. If the adhesion area of the tip portion 293a to the substrate W is small, the desired adhesion force may not be obtained. In this case, misalignment or the like may occur when transporting the substrate W. On the other hand, if the adhering area of the tip portion 293a to the substrate W is large, it may be difficult to peel off from the substrate W, and the throughput of handling the substrate W may be reduced. Furthermore, if the adhering portion of the substrate W of the tip portion 293a is large, the possibility of contamination of the substrate W increases. Therefore, it may be preferable to design the size and material of the tip portion 293a and the second adhesion pad 277a by taking them into consideration.

The controller 292 controls the operation of the first adhesion pad 286a. In the substrate transfer apparatus according to one or more embodiments, the controller 292 controls the air pressure in the cavity 290 through the passage 291. For example, in the state of FIG. 6A, the controller 292 controls the cavity 290 to the first pressure. Next, when shifting to the state of FIG. 6B, the controller 292 controls the air pressure of the cavity 290 to the second pressure which is lower than the first pressure. For example, when the first pressure is an ambient pressure, the second pressure may be a negative pressure lower than the ambient pressure. Further, when the first pressure is positive pressure, the second pressure may be the ambient pressure. Further, when shifting to the state of FIG. 6C, the controller 292 controls the third pressure which is higher than the first pressure. For example, when the third pressure is the ambient pressure, the first pressure may be negative pressure. Further, when the first pressure is the ambient pressure, the third pressure may be positive pressure. Here, in order to reduce contamination from particulate matter, scientific substances, or biological substances from the substrate transport environment, it may be preferable to keep the cavity 290 in a negative pressure state at all times. For example, the controller 292 may control the cavity 290 to a first pressure that is a negative pressure lower than the ambient pressure, and the second pressure lower than the first pressure. Further, it may be preferable to use CDA (Clean Dry Air) when positive pressure is used.

In FIG. 6A, when the controller 292 controls the pressure of the cavity 290 to the first pressure, the first adhesion pad 286a is flat and substantially parallel to the cover 272a. The second adhesion pad 277a is placed in the recess and adheres to the substrate W. The surface of the tip portion 293a of the first adhesion pad 286a and the surface of the second adhesion pad 277a are arranged at a substantially constant height. The cavity 290 has a sufficient area. In this case, the tip portion 293a and the second adhesion pad 277a are attached to the substrate W. Next, in the state of FIG. 6B, that is, when the controller 292 controls the air pressure of the cavity 290 to a second pressure lower than the first pressure, the first adhesion pad 286a deformed into a recessed shape toward the cavity 290 due to the difference in air pressure in the cavity 290 and the external air pressure. As a result, the adhesion to the substrate W is released from the center of the tip portion 293a and the second adhesion pad 277a, and eventually, only the periphery of the tip portion 293a adheres to the substrate W. In this state, a sealed space is generated between the second adhesion pad 277a and the substrate W. This space is created because the center of the first adhesion pad 286a is depressed by controlling the cavity 290 to the second pressure. Since the space is sealed and has a low pressure compared to the outside pressure, the first adhesion pad 286a has a higher grip with respect to the substrate W. Next, in the state of FIG. 6C, that is, when the controller 292 is controlled to a third pressure higher than the first pressure, the first adhesion pad 286a changes to the shape in which the cavity 290 is inflated due to the difference in pressure in the cavity 290. As a result, the adhesion between the periphery of the tip portion 293a and the substrate W is released, and eventually, the center of the tip portion 293a and the second adhesion pad 277a are attached to the substrate W. Since only the center of the tip portion 293a and the second adhesion pad 277a are attached to the substrate W, the first adhesion pad 286a has a lower grip on the substrate W compared to the state of FIG. 6A.

Here, in the hand 270 according to one or more embodiments, as shown in FIG. 6A, in the state of the first pressure, the tip portion 293a and the second adhesion pad 277a are adhered to the substrate W, and in the state of the second pressure as shown in FIG. 6B, only the periphery of the tip portion 293a is attached to the substrate W, and further, in the state of the third pressure as shown in FIG. 6C, a part of the tip portion 293a and the second adhesion pad 277a are attached to the substrate W. However, it is not limited thereto, for example, in the state of the first pressure, a part of the tip portion 293a and the second adhesion pad 277a may adhere to the substrate W, and in the state of the second pressure, if the space is sealed, the second adhesion pad 277a may be adhered to the substrate W. Further, in the state of the third pressure, only the second adhesion pad 277a may be attached to the substrate W.

As described above, in the substrate transfer apparatus according to one or more embodiments, the first adhesion pad 286a and the second adhesion pad 277a adheres to the substrate W based on the control of the controller 292. For example, when a misalignment at the time of movement needs to be reduced and high accuracy is required for the placement of the substrate W such as transportation from the pre-aligner device to the load lock device, the first adhesion pad 287a and the second adhesion pad 277a having high adhesion are attached to the substrate W. Further, in the substrate transfer apparatus according to one or more embodiments, the first adhesion pad 286a is deformed to create a space between the first adhesion pad 286a and the substrate W. Since the space has an pressure lower than the outside pressure, the first adhesion pad 286a has a higher grip on the substrate W. On the other hand, when high accuracy is not required for the placement of the substrate W, for example, from the load port device to the pre-aligner device or from the load lock device to the load port device, the first adhesion pad 286a is deformed based on the control of the controller 292, a part of the tip portion 286a and the second adhesion pad 277a may adhere to the substrate W. As a result, the adhesion force to the substrate W on the hand 270 is reduced, but the substrate transfer speed may be improved. Thus, the adhesion force to the substrate W is controlled by transforming the first adhesion pad 286a provided in the hand 270 and changing the adhesion area between the first adhesion pad 286a and the substrate W, and the gripping force during transfer may be changed depending on the required accuracy.

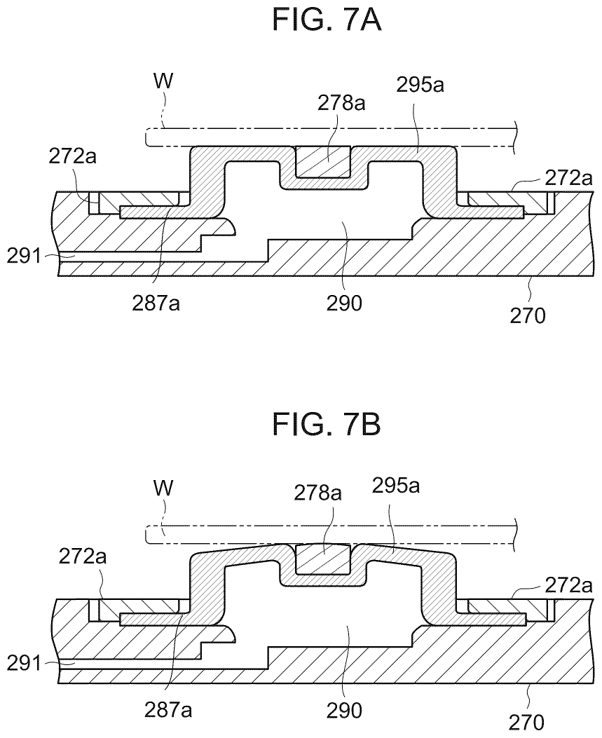

FIGS. 7A and 7B are diagrams illustrating for example, A-A cross-sectional view of FIG. 2 of the substrate transfer apparatus according to one or more embodiments. In FIG. 7A, the hand 270 includes the first adhesion pad 287a, the second adhesion pad 278a, the cover 272a covering the first adhesion pad 287a, and the cavity 290 provided inside the hand 270. The cavity 290 is connected to the passage 291. The inside of the passage 291 forms a continuous hollow space extending from the cavity 290. Thereby, the air pressure of the cavity 290 is changed by controlling the air pressure of the passage 291. The first adhesion pad 287a includes a flat plate shaped flat portion and the tip portion 295a in the substantially center of the flat portion. The flat plate shaped end of the first adhesion pad 287a is sandwiched between the hand 270 and the cover 272a. Further, the flat plate shape of the first adhesion pad 287a is integrally formed with the tip portion 295a, and the tip portion 295a seals the cavity 290. Thereby, the cavity 290 has a structure having a sealed state blocked from the external environment. The tip portion 295a has a recess substantially in the center, and the second adhesion pad 278a is placed in a recess.

In FIG. 7A, the tip portion 295a of the first adhesion pad 287a is protruded from the opening of the cover 272a. When the substrate W is placed on the hand 270, the tip portion 295a adheres to and grips the substrate W. In the state of FIG. 7A, the tip portion 295a adheres to the substrate W in a predetermined area. Further, the second adhesion pad 278a adheres to the substrate W in a predetermined area.

The tip portion 295a of the first adhesion pad 287a and the second adhesion pad 278a grip the substrate W by adhesion force. The tip portion 295a and the second adhesion pad 278a may adhere to the substrate W with stickiness force and friction force. The adhesion force may refer to the force that adheres to the substrate W at least one of the stickiness or friction force. Therefore, the tip portion 295a and the second adhesion pad 278a may adhere to the substrate W with either stickiness force or friction force. Here, the stickiness force may be defined as the force that pulls off two bonded objects. The friction force may be defined as the force generated when two objects come into contact and try to move relatively. The stickiness force generates a force that resists forces in various directions. On the other hand, the friction force generates a force in the opposite direction to the direction of motion of two objects. The tip portion 295a of the first adhesion pad 287a and the second adhesion pad 278a may have different adhesion forces. For example, when the tip portion 295a has the first adhesion force, the second adhesion pad 278a may have the second adhesion force that is weaker than the first adhesion force. Furthermore, the tip portion 295a and the second adhesion pad 278a may include different materials.

The first adhesion pad 287a may include silicon rubber, elastomeric polyimide fiber, fluorine rubber, polyurethane, or the like. Further, the first adhesion pad 287a may use a technique using biomimetics (biomimetic technology) that analyzes excellent functions and applies them engineering. For example, a reversible bonding technology that may repeatedly perform adhesion and separation, an adhesive technology using Van der waals force, and a dry adhesive technology that exhibits adhesive strength without using a sticky liquid. The second adhesion pad 278a may include silicon rubber, elastomeric polyimide fibers, fluorine rubber, polyurethane, and the like. Further, the second adhesion pad 278a may have an adhesion force only by friction force. In other words, the second adhesion pad 278a may include a non-stickiness material.

FIG. 7B is A-A cross-sectional view of FIG. 2, for example. In FIG. 7B, based on the control of the controller 292, the tip portion 295a of the first adhesion pad 287a is deformed. As a result of the deformation in FIG. 7B, the center of the tip portion 295a and the second adhesion pad 278a adhere to the substrate W. Based on the control of the controller 292, the periphery of the tip portion 295a is separated from the substrate W, and the center of the tip portion 295a and the second adhesion pad 278a adhere to the substrate W. In this state, since the substrate W is attached only to the center of the tip portion 295a and the second adhesion pad 278a, the first adhesion pad 287a has a lower grip compared to FIG. 7A.

The area to which the substrate W adheres to the tip portion 295a is preferably an area of 2 mm to 30 mm in diameter, and furthermore, the tip portion 295a may be preferably adhered to an area of 5 mm to 15 mm in diameter. Further, it may be preferable that the area in which the second adhesion pad 278a adheres to the substrate W is small, and point contact may be preferable for the area where the second adhesion pad 278a adheres to the substrate W.

In the state of FIG. 7A, the tip portion 295a and the second adhesion pad 278a adhere to the substrate W. Next, as in the state of FIG. 7B, when the cavity 290 is inflated, the periphery of the tip portion 295a is separated from the substrate W, and only the center of the tip portion 295a and the second adhesion pad 278a are adhered to the substrate W. In this state, only the center of the tip portion 295a and the second adhesion pad 277a adhere to the substrate W, thus having a lower gripping force compared to FIG. 7A.

In FIG. 7A, when the substrate W is placed on the hand 270, the tip portions 295a and the second adhesion pad 278a of the first adhesion pad 287a are attached to the substrate W. For example, when high accuracy is required for the placement of the substrate W, such as transportation from the pre-aligner device to the load lock device, the tip portion 295a and the second adhesion pad 278a adhere to and grip the substrate W. Thereby, the misalignment of the substrate W may be reduced.

On the other hand, when high accuracy is not required for the placement of the substrate W, for example, from the load port device to the pre-aligner device or from the load lock device to the load port device, the cavity 290 is inflated and the center of the first adhesion pad 287a is lifted, as shown in FIG. 7B. As a result, the periphery of the tip portion 295a shown in FIG. 7B is separated from the substrate W and the adhesion is released. The center of the tip portion 293a and the second adhesion pad 278a are attached to the substrate W. Thereby, it may be possible to process transporting the substrate W and handling to other devices at high speed.

As shown in FIG. 2, the tip portions 282a, 282b and 282c of the adhesion pads 280a, 280b and 280c show a circular shape when viewed from above, but the first adhesion pad 287a and the second adhesion pad 278a shown in FIGS. 7A and 7B may be implemented without limitation. If the adhesion area of the substrate W of the tip portion 295a is small, the desired adhesion force may not be obtained. In this case, a possibility of misalignment or the like may occur when transporting the substrate W. On the other hand, if the adhering portion of the substrate W of the tip portion 295a is large, it may be difficult to peel off from the substrate W, and the throughput of handling the substrate W may be reduced. Furthermore, if the adherence portion of the substrate W of the tip portion 295a is large, the possibility of contamination of the substrate W increases. Therefore, it may be preferable to design the size and material of the tip portion 295a and the second adhesion pad 278a by taking them into consideration.

The controller 292 controls the operation of the first adhesion pad 287a. In the substrate transfer apparatus according to one or more embodiments, the controller 292 controls the air pressure in the cavity 290 through the passage 291. For example, in the state of FIG. 7A, the controller 292 controls the cavity 290 to the first pressure. Next, when moving on to the state of FIG. 7B, the controller 292 controls the air pressure in the cavity 290 to the second pressure which is higher than the first pressure. For example, when the first pressure is an ambient pressure, the second pressure may be a positive pressure higher than the ambient pressure. Further, when the second pressure is the ambient pressure, the first pressure may be a negative pressure lower than the ambient pressure. Here, in order to reduce contamination from particulate matter, scientific substances, or biological substances from the substrate transport environment, it may be preferable to keep the cavity 290 in a negative pressure state at all times. For example, the controller 292 may control the cavity 290 to the first pressure that is a negative pressure lower than the ambient pressure, and the second pressure lower than the first pressure. Further, it may be preferable to use CDA (Clean Dry Air) when positive pressure is used.

In FIG. 7A, when the controller 292 controls the pressure of the cavity 290 to the first pressure, the first adhesion pad 287a is flat and substantially parallel to the cover 272a. The second adhesion pad 278a is placed in the recess and adheres to the substrate W. The cavity 290 has a sufficient area. In this case, the tip portion 295a and the second adhesion pad 278a adhere to the substrate W. Next, in the state of FIG. 7B, that is, when the controller 292 is controlled to a second pressure which is higher than the first pressure, the first adhesion pad 287a changes to the shape in which the cavity 290 is inflated due to the difference in air pressure in the cavity 290 and the external pressure. As a result, the adhesion between the periphery of the tip portion 295a and the substrate W is released, and eventually, the center of the tip portion 295a and the second adhesion pad 278a are attached to the substrate W. Since only the center of the tip portion 295a and the second adhesion pad 278a are attached to the substrate W, the first adhesion pad 287a has a lower grip to the substrate W compared to the state of FIG. 7A.

Here, in the hand 270 according to one or more embodiments, in the state of first pressure as shown in FIG. 7A, the tip portion 295a and the second adhesion pad 278a are adhered to the substrate W, in the state of the second pressure and as shown in FIG. 7B, only the center of the tip portion 295a and the second adhesion pad 278a are adhered to the substrate W. However, it is not limited thereto, for example, a part of the tip portion 295a and the second adhesion pad 278a may adheres to the substrate W in the state of the first pressure, and only the second adhesion pad 278a may adheres to the substrate W in the state of the second pressure.

As described above, in the substrate transfer apparatus according to one or more embodiments, the first adhesion pad 287a and the second adhesion pad 278a are attached to the substrate W based on the control of the controller 292. For example, when misalignment during transfer needs to be reduced and high accuracy is required for the placement of the substrate W such as transportation from the pre-aligner device to the load lock device, the first adhesion pad 287a and the second adhesion pad 278a having high adhesion adhere to the substrate W. On the other hand, when high accuracy is not required for the placement of the substrate W, for example, from the load port device to the pre-aligner device or from the load lock device to the load port device, the first adhesion pad 287a is deformed based on the control of the controller 292, and only a part of the first adhesion pad 287a and the second adhesion pad 278a adhere to the substrate W. As a result, the adhesion force to the substrate W on the hand 270 is reduced, but the substrate transfer speed may be improved. Thus, the adhesion force to the substrate W is controlled by deforming the first adhesion pad 287a provided in the hand 270 and changing the adhesion area between the first adhesion pad 287a and the substrate W, and the gripping force during transfer may be changed depending on the required accuracy.

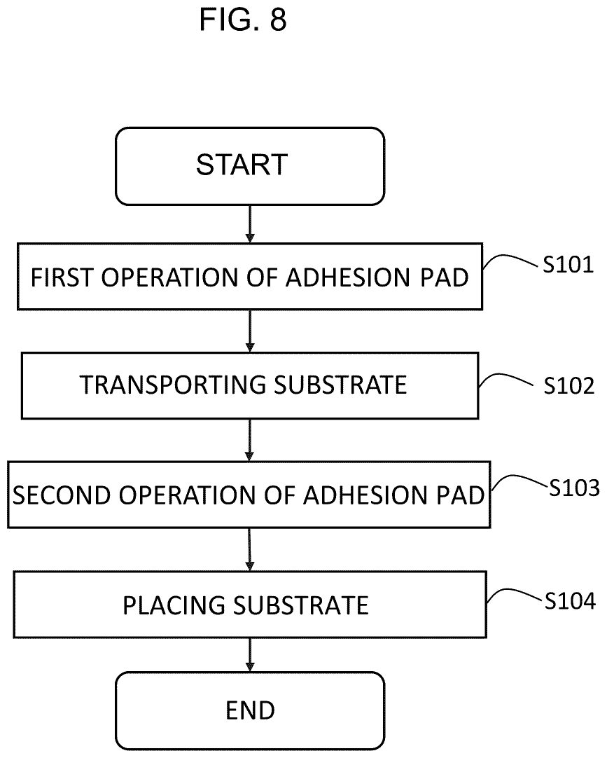

FIG. 8 is a flowchart illustrating a substrate transfer method according to one or more embodiments. First, the first operation is performed on the adhesion pad (step S101). In the first operation, for example, as shown in FIG. 3A, the substrate W is placed on the hand 270, and the tip portion 282a of the adhesion pad 280a grip the substrate W by adhering to the substrate W based on the control of the controller 292. The cavity 290 of the hand 270 is set, for example, to the first pressure by the control of the controller 292. Thereby, the tip portion 282a attaches the substrate W in the first area. Here, when the first pressure is approximately ambient pressure, pressure control of the cavity 290 by the controller 292 may not be necessary. Therefore, in this case, step S101 is a step that may not necessarily be performed.

Next, the substrate W is transported (step S102). For example, when high accuracy is required for the placement of the substrate W, such as transportation from the pre-aligner device to the load lock device, the adhesion pad 280a having high adhesion is attached to the substrate W in the first area and transported. In other words, when the tolerance for misalignment of the substrate W is small, the adhesion pad 280a having high adhesion adhere in the first area. Thereby, the misalignment of the substrate W may be reduced. At this time, the transfer speed of the substrate W may be a relatively slow first speed.

Next, the second operation of the adhesion pad is performed (step S103). The second operation deforms the adhesion pad 280a based on the control of the controller 292 as shown in FIG. 3C, for example. When the adhesion pad 280a is deformed, the cavity 290 of the hand 270 is set to the second pressure lower than the first pressure by the control of the controller 292. Thereby, due to the difference in air pressure between the air pressure of the cavity 290 and the external air pressure, the adhesion pad 280a changes to a shape recessed on the cavity 290 side. Accordingly, the tip portion 282a adheres to the substrate W in the second area which is smaller than the first area. Since the area where the adhesion pad 280a adheres to the substrate W is reduced, the gripping force of the adhesion pad 280a on the substrate W decreases.

Next, the substrate W is placed in a state where the area of the adhesion pad 280a adheres to the substrate W is the second area (step S104). For example, when high accuracy is not required for the placing the substrate, such as placement from the load port device to the pre-aligner device or from the load lock device to the load port device, the area where the adhesion pad 280a adheres to the substrate W is reduced and placed. In other words, when there is a high the tolerance for the misalignment of the substrate W, the area where the adhesion pad 280a adheres to the substrate W is reduced. Thereby, the substrate W may be transported at high speed to be moved to the destination device at high speed. For example, the conveying speed of the substrate W may be a second speed faster which is faster than the first speed.

Here, when transporting the substrate W in steps S103 and S106, the transfer speed may be changed. Further, in the substrate transfer apparatus according to one or more embodiments, the second operation of the adhesion pad may be performed (step S103) after the substrate W is placed (step S104) with the area of the adhesion pad 280a adhering to the substrate W being the second area. In particular, with regard to the operation control of the substrate transfer apparatus including a plurality of hands, reference is made to U.S. Pat. No. 12,036,680.

In the substrate transfer method according to one or more embodiments as described above, the adhesion pad is deformed to change the adhesion area of the substrate W and the adhesion pad. By changing the adhesion area of the substrate W and the adhesion pad, it may be possible to change the adhesion force to the hand at the time of substrate transportation depending on the required accuracy. Thereby, it may be possible to improve the productivity of the semiconductor device by optimizing the transfer speed of the substrate, and it may also contribute to reducing substrate damage during substrate transportation.

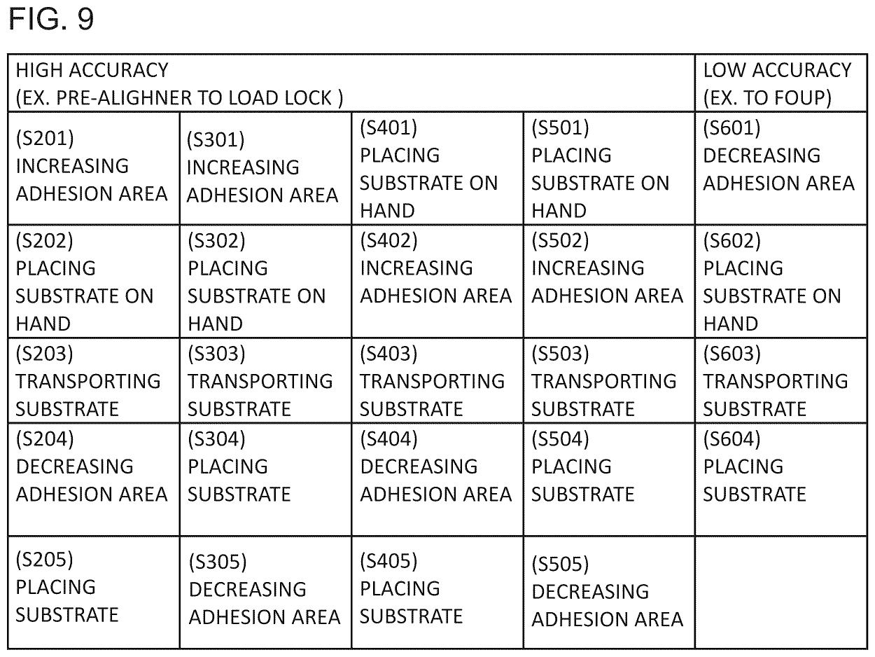

FIG. 9 is a diagram illustrating a substrate transfer method according to one or more embodiments. In FIG. 9, the hand 270 according to FIG. 2 is described as an example of a substrate transfer method related to transportation that requires high accuracy, such as a pre-aligner device to a load lock device, and a substrate transportation method related to transportation that does not require high accuracy, such as substrate transportation related to a FOUP. In the following description, a load lock device will be described as an example as a transport destination where high accuracy is required, but is not limited thereto.

In the substrate transfer method according to one or more embodiments when high accuracy is required, first, increasing the adhesion area of the tip portions 282a, 282b and 282c of the adhesion pads 280a, 280b and 280c and the substrate W based on the control of the controller 292 (step S201). Next, the substrate W is placed on the hand 270 with the adhesion area of the tip portions 282a, 282b and 282c and the substrate W being increased (step S202). Next, the substrate W is transported (step S203). Next, as a second operation, the adhesion area of the tip portions 282a, 282b and 282c of the adhesion pads 280a, 280b and 280c and the substrate W is reduced based on the control of the controller 292 (step S204). Next, the substrate W is placed on a device such as a load lock device while the adhesion area of the tip portions 282a, 282b, and 282c and the substrate W is reduced (step S205).

In the substrate transfer method according to one or more embodiments when high accuracy is required, first, the adhesion area of the tip portions 282a, 282b and 282c of the adhesion pads 280a, 280b and 280c and the substrate W is increased based on the control of the controller 292 (step S301). Next, the substrate W is placed on the hand 270 with the adhesion area of the tip portions 282a, 282b and 282c and the substrate W being increased (step S302). Next, the substrate W is transported (step S303). Next, the substrate W is placed on a device such as a load lock device while the substrate W is placed on the hand 270 with the adhesion area of the tip portions 282a, 282b and 282c and the substrate W is increased (step S304). Next, as a second operation, the adhesion area of the tip portions 282a, 282b and 282c of the adhesion pads 280a, 280b and 280c and the substrate W is reduced based on the control of the controller 292 (step S305).

In the substrate transfer method according to one or more embodiments when high accuracy is required, the substrate W is placed on the hand 270 (step S401). Next, as a first operation, the adhesion area of the tip portions 282a, 282b and 282c of the adhesion pads 280a, 280b and 280c and the substrate W is increased (step S402). Next, the substrate W is transported (step S403). Next, as a second operation, the adhesion area of the tip portions 282a, 282b and 282c and the substrate W is reduced (step S404). Next, the substrate W is placed on a device such as a load lock device while the adhesion area of the tip portions 282a, 282b and 282c and the substrate W is reduced (step S405).

In the substrate transfer method according to one or more embodiments when high accuracy is required, first, the substrate W is placed on the hand 270 (step S501). Next, as a first operation, the adhesion area of the tip portions 282a, 282b and 282c of the adhesion pads 280a, 280b and 280c with the substrate W is increased based on the control of the controller 292 (step S502). Next, the substrate W is transported (step S503). Next, the substrate W is placed on a device such as a load lock device with the adhesion area of the tip portions 282a, 282b and 282c and the substrate W being increased (step S504). Next, the adhesion area of the tip portions 282a, 282b and 282c and the substrate W is reduced (step S505).

Next, a substrate transfer method related to transportation that does not require high accuracy, such as substrate transportation to a FOUP, is described. As a first operation, the substrate transfer method according to one or more embodiments when high accuracy is not required, the adhesion area of the tip portions 282a, 282b and 282c of the adhesion pads 280a, 280b, 280c and 280d and the substrate W is reduced based on the control of the controller 292, (step S601). The substrate W is placed on the hand 270 with the tip portions 282a, 282b, 282c and 282d stored (step S602). Next, the substrate W is transported (step S603). Next, the substrate W is placed on the load lock device with the adhesion area of the tip portions 282a, 282b and 282c and the substrate W being reduced (step S604).

Thus, in the substrate transfer method according to one or more embodiments, the area where the adhesion pad adheres to the substrate is increased to increase the gripping force during transfer which requires high accuracy, such as transporting from a pre-aligner device to a load lock device or the like. Normally, when transferring a substrate that requires high accuracy, the speed is reduced to transport the substrate. In the substrate transfer method according to one or more embodiments, the gripping force may be controlled by controlling the adhesion pad even when high accuracy is required for transferring. This may minimize the reduction in speed. As a result, the number of lots per unit passing through the production line and the time required to pass through the production line (Turn around time: TAT) may be improved.

Further, in the substrate transfer method according to one or more embodiments, the adhesion force of the adhesion pad is used, and the adhesion area of the adhesion pad is increased during transfer when acceleration and deceleration is applied to the substrate, and then the adhesion area of the adhesion pad is reduced when the transfer is completed or the substrate W is placed on the FOUP, for example. Thereby, it may be possible to reduce the adverse effect of the adhesion force of the adhesion pad. Further, even when transporting where high accuracy is required, the decrease in speed may be minimized. In addition, the number of lots per unit passing through the production line and the time required to pass through the production line (Turn around time: TAT) may be improved.

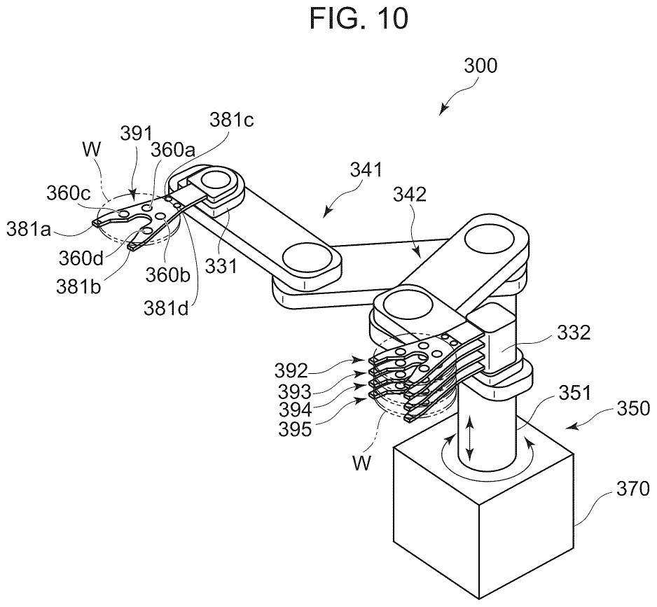

FIG. 10 is a diagram illustrating the substrate transfer apparatus 300 according to one or more embodiments. The substrate transfer apparatus 300 includes the base 370, the elevator 350, and a substrate transfer mechanism. The substrate transfer apparatus 300 is a substrate transfer apparatus having a horizontal articulation. That is, the substrate transfer apparatus 300 includes the first arm 341 and the second arm 342, which are horizontally articulated robot arms, as a substrate transport mechanism. The first arm 341 and the second arm 342 each have two links. The two links are rotatably connected to each other horizontally. The first arm 341 and the second arm 342 are connected to the elevator 350. One end of the first arm 341 and the second arm 342 are rotatably connected horizontally with respect to the lifting shaft 351 of the elevator 350. The elevator 350 moves the first arm 341 and the second arm 342 up and down by moving the lifting shaft 351 along the vertical direction. The first arm 341, the second arm 342, and the elevator 350 are operated by the driving force of a servo motor (not shown).

The first blade support 331 is provided at the other end of the first arm 341. Then, the second blade support 332 is provided at the other end of the second arm 342. The first blade support 331 is rotatably connected to the first arm 341 horizontally. Further, the second blade support 332 is rotatably connected to the second arm 342 horizontally.

In the substrate transfer apparatus 300, the first blade support 331 supports the blade 391. The second blade support 332 supports a plurality of blade 392, blade 393, blade 394 and blade 395. The substrate transfer apparatus 300 performs an operation of transporting one substrate W by a blade 391 supported by the first blade support 331, and an operation of simultaneously transporting a plurality of substrate W by a plurality of blades 392, 393, 394 and 395 supported by the second blade support 332.

The blade 391 includes the adhesion pads 360a, 360b, 360c and 360d that grip the placed substrate W. The blade 391 may have a structure similar to the hand 270 shown in FIG. 2. For example, blade 391 may include a passage. The adhesion pads 360a, 360b, 360c and 360d each include a tip having high adhesion (not shown), which adheres to the substrate W. Next, the tip portions of the adhesion pads 360a, 360b, 360c and 360d are deformed under the control of the controller, and the area where the tip adheres to the substrate W is reduced. As the area where the tip portion adheres to the substrate W decreases, the gripping force of the tip portion to the substrate W decreases.

Here, an example is explained in which the adhesion pads 360a, 360b, 360c and 360d that grip the placed substrate W are provided on the blade 391. Not limited thereto, adhesion pads 360a, 360b, 360c and 360d may be provided on the plurality of blades 392, 393, 394 and 395 of the second blade support 332.

As described above, in the substrate transfer apparatus according to one or more embodiments, including a plurality of arms, the adhesion pad 260a, 260b 260c and 260d, based on the control of 292 controllers, may be able to change the adhesion force at the time of transportation according to the required accuracy by controlling the area to which the gripped substrate W adheres. The entire contents of the international publication No. WO2023/210561, in particular the description of a substrate transfer apparatus having a plurality of arms, are incorporated herein by reference.

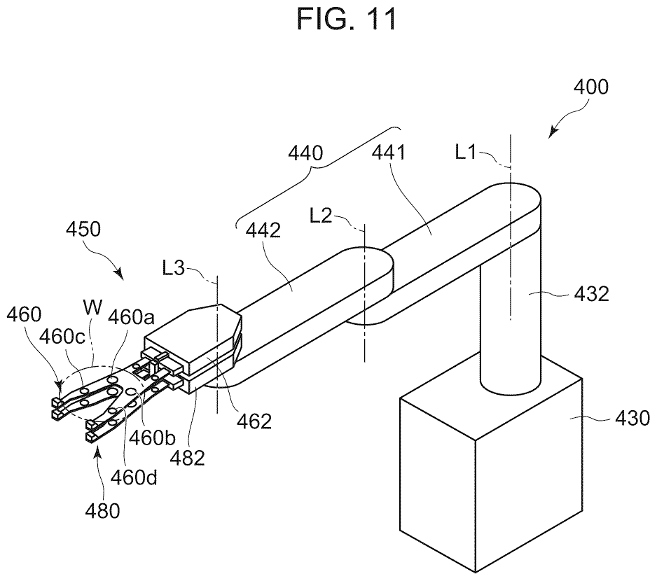

FIG. 11 is a perspective view showing the substrate transfer apparatus 400 according to one or more embodiments. The substrate transfer apparatus 400 is a transport robot for gripping and transporting the semiconductor substrate W in a clean room where the semiconductor is manufactured. The substrate transfer apparatus 400 is a so-called horizontally articulated three-axis robot, including the base 430, the elevator 432 provided on the upper surface of the base 430, the arm 440 attached to the upper end of the elevator 432, and the end effector 450 attached to the wrist of the arm 440. The elevator 432 is arranged to be extendable in a vertical direction by an air cylinder (not shown) or the like. The elevator 432 is provided rotatable around the first rotation axis L1 extending vertically with respect to the base 430. The robot arm 440 includes a first link 441 and the second link 442, both of which include a long member extending horizontally. In the first link 441 is attached to the upper end of the elevator 432 at an end of the longitudinal direction. The first link 441 is integrally raised and lowered with the elevator 432 and rotates around the first rotation axis integrally with the elevator 432. The second link 442 is rotatably attached around the second rotation axis L2 where the longitudinal end extends vertically to the other longitudinal end of the first link 441.

The end effector 450 is attached to the other end in the longitudinal direction (the wrist of the robot arm) of the second link 442. The end effector 450 includes the first end effector 460 and the second end effector 480 provided independently rotatable around the same third rotation axis L3 extending vertically. In one or more embodiments, the second end effector 480 is attached underneath the first end effector 460. The first end effector 460 and the second end effector 480 may have the same external shape as each other in a planar view. The first end effector 460 and the second end effector 480 each perform an operation of griping the substrate W independently of each other.

The first end effector 460 includes a first wrist axis (not shown) extending vertically about the third rotation axis L3 and the first end effector base 462 having a hollow structure connected to the upper end of the first wrist axis. The second end effector 480 is provided outside the first wrist axis, and includes the second wrist axis (not shown) extending in a vertical direction about the third rotation axis L3, and the second end effector base 482 having a hollow structure connected to the upper end of the second wrist axis.

The first end effector 460 is driven by a drive source including a servo motor or the like. The first end effector 460 rotates around the third rotation axis L3 vertically by the driving force generated by the drive source. Further, the second end effector 480 is driven by a drive source including a servo motor or the like. The second end effector 480 rotates around the third rotation axis L3 extending vertically by the driving force generated by the drive source. The first end effector 460 and the second end effector 480 may be rotated independently.

The hands of the first end effector 460 and the second end effector 480 may have the structure of the hand 270 of FIG. 2. For example, the hands of the first end effector 460 and the second end effector 480 include adhesion pads (not shown) that grip the placed substrate W. FIG. 11 shows the adhesion pads 461a, 461b, 461c and 461d provided in the first end effector 460. The hands of the first end effector 460 and the second end effector 480 may include passages, such as the structure of the hand 270 shown in FIG. 2. The adhesion pads 461a, 461b, 461c and 461d include highly adherent tip portions (not shown) and adhere to the substrate W. The adhesion pads 461a, 461b, 461c and 461d are controlled by the controller through a passage provided inside the hands of the first end effector 460 and the second end effector 480. A passage leading from the adhesion pads 461a, 461b, 461c and 461d is connected to the controller. Under the control of the controller, the tip portions of the adhesion pads 461a, 461b, 461c and 461d adhere to the substrate W. Next, the shape of the tip portions of the adhesion pads 461a, 461b, 461c and 461d changes due to the control of the controller and adheres to the substrate W. As the shape of the tip portion changes, the adhesion area with the substrate W changes.

As described above, in the substrate transfer apparatus according to one or more embodiments, the robot arm 440 includes the hand of the first end effector 460 and the hand of the second end effector 480, and based on the control of the controller, the shape of the tip portions of the adhesion pad 461a 461b, 461c and 461d provided on the hand change, and adhere to the substrate W. Since the adhesion area with the substrate W changes due to the change in the shape of the tip portions, the adhesion force at the time of transportation may be changed according to the required accuracy. The entire contents of the U.S. Pat. No. 11,207,775, in particular a description of a substrate carrying device having a plurality of hands, are incorporated herein by reference.

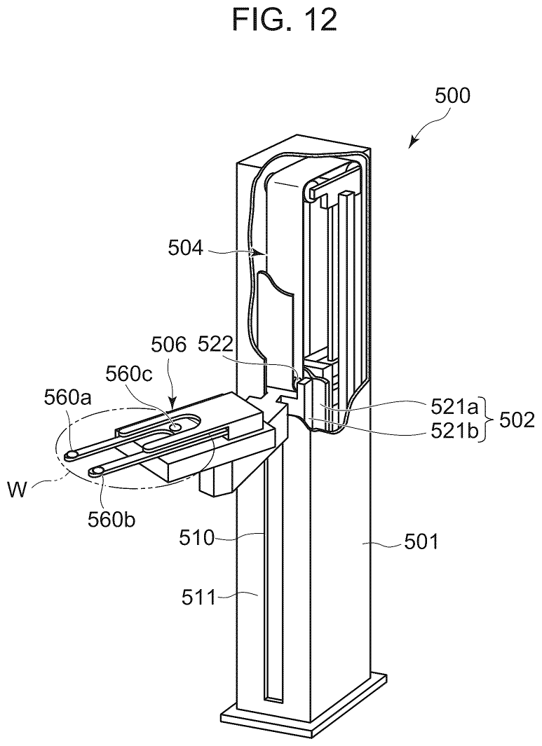

FIG. 12 is a partially fractured perspective view of the substrate transfer apparatus 500 according to one or more embodiments. The substrate transfer apparatus 500 is, for example, an apparatus used for transporting the substrate W in facilities for various process processing such as heat treatment, impurity introduction treatment, thin film formation treatment, lithography treatment, cleaning treatment, and flattening treatment on the substrate. The substrate transfer apparatus 500 may include a dustproof mechanism for preventing particles generated by the drive unit provided inside from flowing outward. The substrate transfer apparatus 500 includes the housing 501, the elevator 502, the sealing belt 504, and the hand 506.

The housing 501 is a box shaped body. The housing 501 includes an opening 510 extending in a predetermined direction. The opening 510 has a rectangular shape in which the housing 501 extends in a straight line perpendicular to the front wall 511. The elevator 502 extends inside and outside the housing 501 through the opening 510. Then, the hand 506 is provided in a portion extending outside the housing 501.

In the substrate transfer apparatus 500 according to one or more embodiments, the elevator 502 includes the internal material 521a placed inside the housing 501 further than the opening 510, and the external material 21b placed outside the housing 501 further than the opening 510. The hand 506 is provided on the external material 521b. The roller 522 is a cylindrical body extending in the width direction of the opening 510 and is provided near the opening 510 of the internal material 521a. The roller 522 is rotatably supported at both ends against the elevator 502 and is mounted so that it rotates around a rotation axis extending in the width direction of the opening 510. The roller 522 moves up and down by the sealing belt 504, and the elevator 502 moves up and down accordingly. Thereby, the hand 506 moves up and down.

The hand 506 may have the structure of hand 270 shown in FIG. 2. For example, the hand 506 includes adhesion pads 560a, 560b, 560c and 560d that adhere to the placed substrate W. The hand 506 may include passages, such as the structure of hand 270 shown in FIG. 2. The adhesion pads 560a, 560b, 560c and 560d include tip portions having high adhesion and adhere to the substrate W. Further, based on the control of the controller, the shape of the tip portions of the adhesion pads 560a, 560b, 560c and 560d changes. Thereby, the adhesion area with the substrate W changes.

As described above, in the substrate transfer apparatus according to one or more embodiments, a so-called direct-acting hand is included, the shape of the tip portions of the adhesion pads 560a, 560b, 560c and 560d changes based on the control of the controller so as to adhere to the substrate W. Since the adhesion area with the substrate W changes as the shape of the tip portions change, it may be possible to change the adhesion force at the time of transportation depending on the required accuracy. The entire contents of the U.S. Pat. No. 10,083,851, in particular a description of a substrate transfer apparatus having a so-called direct-acting hand, are incorporated herein by reference.

As described above, the substrate transfer apparatus according to one or more embodiments has been described, but is not limited thereto, and may be applied, for example, to a hand included in a panel transfer robot. The entire contents of the U.S. patent application publication No. 2005/0090257, in particular the description of a substrate transfer apparatus having a hand, are incorporated herein by reference. Further, one or more of the above-described embodiments may also be applied to the hand used in the FEFEM (Equipment front end module), which is an apparatus that is passed between the FOUP and the process device when passing the substrate to the process device.

As described above, in the substrate transfer apparatus according to one or more embodiments, the shape of the tip portion of the adhesion pad provided on the hand is changed. Thereby, by changing the adhesion force to the substrate, it may be possible to adjust the adhesion force to the substrate at the time of transportation according to the required accuracy.

In addition, the transferring speed of the substrate may be optimized by changing the adhesion force of the hand to the substrate at the time of transportation. Thereby, the productivity of the semiconductor device may be improved by optimizing the transfer speed of the substrate W, and it may be possible to contribute to reducing substrate damage during substrate transportation. The substrate transfer apparatus according to one or more embodiments is particularly useful when suction grips or clamp grips may not be used in consideration of air contamination in the clean room and damage to the substrate.

Furthermore, in today's substrates, complex processing is performed and the friction coefficient of the surface state may differ depending on the type of substrate. The substrate transfer apparatus according to one or more embodiments may control the grip on the hand by considering the friction coefficient of the substrate surface and other factors. As a result, it may be possible to flexibly handle various substrates.

The substrate transfer apparatus according to one or more embodiments has been described. Not limited thereto, for various types of substrate transport apparatus, structures such as hands and adhesion pads used for substrate transport apparatus according to one or more embodiments described above may be used.

One or more embodiments described above herein may be combined with each other as far as practicable within the scope of the intended embodiment. The above examples should be considered exemplary in all respects and not limiting. The illustrated and described embodiments may be extended to include other embodiments in addition to those specifically delivered, without departing from the technical scope. The technical scope should be determined not only by the foregoing description, but also in the light of the specification containing equivalents. Thus, all configurations, including the equal technical scope, are intended to be included in the technical scope.

1. A substrate transfer apparatus comprising:
a base;
an elevator connected to the base freely raised and lowered; and
a substrate transfer mechanism comprising a hand that is movably connected to the elevator and transports a substrate, wherein
the hand comprises an adhesion pad that adheres to the substrate and grip the substrate, the adhesion pad changes a gripping force with the substrate by deformation of the adhesion pad.

2. The substrate transfer apparatus according to claim 1, wherein
the adhesion pad changes the gripping force with the substrate as an area that adheres to the substrate changes.

3. The substrate transfer apparatus according to claim 1, wherein the hand comprises:
a cavity arranged inside the hand; and
a cover arranged to cover the cavity and comprising an opening arranged essentially in a center, wherein
the adhesion pad adheres to the substrate from the opening.

4. The substrate transfer apparatus according to claim 3, wherein the adhesion pad comprises:
a tip portion that adheres to the substrate and changes an area adhered to the substrate; and
a flat portion sandwiched between the cover and the hand and sealing the cavity.

5. The substrate transfer apparatus according to claim 4, wherein the hand comprises:
a controller that controls a change in an area of the tip portion that adheres to the substrate; and
a passage that is connected to the cavity and transmits the control of the controller.

6. The substrate transfer apparatus according to claim 5, wherein
the controller controls an area where the tip portion adheres to the substrate by changing air pressure in the cavity through the passage.

7. The substrate transfer apparatus according to claim 6, wherein
the controller controls the air pressure in the cavity to a first pressure, so that the tip portion adheres to the substrate with a first area, and
the controller controls the air pressure of the cavity to a second pressure that is lower than the first pressure, so that the tip portion adheres to the substrate with a second area which is smaller than the first area.

8. The substrate transfer apparatus according to claim 6, wherein
the hand further comprises a pad support arranged in the cavity and supporting the tip portion from a bottom surface of the cavity.

9. The substrate transfer apparatus according to claim 8, wherein
the pad support is protruded from the tip portion and comes into contact with the substrate.

10. The substrate transfer apparatus according to claim 9, wherein
an adhesion force of the pad support to the substrate is smaller than an adhesion force of the tip portion to the substrate.

11. The substrate transfer apparatus according to claim 8, wherein the hand further comprises
a second adhesion pad arranged on a surface of the tip portion and supported by the pad support, wherein
an adhesion force of the second adhesion pad to the substrate is smaller than an adhesion force of the tip portion to the substrate.

12. The substrate transfer apparatus according to claim 8, wherein
the tip portion is deformed to generate a space between the tip portion and the substrate, and a pressure in the space is lower than an ambient pressure of the substrate transfer apparatus.

13. The substrate transfer apparatus according to claim 6, wherein the hand further comprises
a second adhesion pad arranged on a surface of the tip portion, wherein
the tip portion and the second adhesion pad adhere to the substrate when the cavity is at a first pressure,
the second adhesion pad adheres to the substrate when the cavity is at a second pressure that is higher than the first pressure.

14. A substrate transfer method comprising:
placing a substrate so that the substrate is in contact with an adhesion pad included in a hand of a substrate transfer apparatus;
adhering a tip portion of the adhesion pad to the substrate in a first area;
transporting the substrate with the substrate placed on the hand;
adhering the tip portion of the adhesion pad to the substrate in a second area that is smaller than the first area; and
placing the substrate from the hand to an apparatus.

15. The substrate transfer method according to claim 14, wherein
the adhering the tip portion of the adhesion pad to the substrate in the second area smaller than the first area, comprising:
changing air pressure in a cavity; and
deforming the tip portion by changing air pressure,
releasing the tip portion partially from adhesion to the substrate due to the deformation of the tip.
